(19) United States
(12) Patent Application Publication
(10) Pub. No.: US 2026/0104815 A1
(43) Pub. Date: Apr. 16, 2026

(54) STORAGE DEVICE

(71) Applicant: Samsung Electronics Co., Ltd., Suwon-si (KR)

(72) Inventor: Eun Chu OH, Suwon-si (KR)

(73) Assignee: Samsung Electronics Co., Ltd., Suwon-si (KR)

(21) Appl. No.: 19/076,625

(22) Filed: Mar. 11, 2025

(30) Foreign Application Priority Data
Oct. 11, 2024 (KR) 10-2024-0138766

(51) Int. Cl. G06F 3/06

(52) U.S. Cl. CPC G06F 3/0655; G06F 3/0619; G06F 3/0679

(57) ABSTRACT

A storage device may include a memory device, a storage controller, log likelihood ratio (LLR) optimization circuit, and an LLR set register configured to a store a symmetric LLR set and an asymmetric LLR set. The memory device may include first memory cells of a first memory page connected to a target wordline. The LLR optimization circuit may be configured to generate a first readout error index for data stored in the first memory cells. The storage controller may be configured to select one of the symmetric LLR set and the asymmetric LLR set based on the first readout error index. The storage controller may include a decoder configured to perform error correction code (ECC) decoding by applying LLR values of the LLR set selected by the LLR set selection circuit to data read from the first memory cells.

### CROSS-REFERENCE TO RELATED APPLICATION

This application claims priority from Korean Patent Application No. 10-2024-0138766 filed on Oct. 11, 2024 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a storage device, and more particularly, to a storage device including an error correction code (ECC) decoder with improved error correction capability.

### 2. Description of the Related Art

A semiconductor memory device may be classified as either a volatile memory device or a nonvolatile memory device, depending on whether it loses stored data when power supply is interrupted. The operation modes of a nonvolatile memory device include: a write mode (or program mode), in which data is stored in memory cells; a read mode, in which stored data is read from memory cells; and an erase mode, in which stored data is deleted to initialize the memory cells. A nonvolatile memory device is used to store information that needs to be preserved regardless of whether power is supplied.

In general, in nonvolatile memory devices, error correction encoding may be performed for data being programmed, and error correction decoding may be performed for data being read. As the memory cells of nonvolatile memory devices become increasingly miniaturized and stacked, the memory cells degrade, and their data retention characteristics deteriorate. Accordingly, during error correction decoding of data read from the memory cells of a nonvolatile memory device, it may be advantageous to take into account the deterioration of the data retention characteristics of the memory cells.

### SUMMARY

Aspects of the present disclosure provide a storage device with improved error correction capability.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an embodiment of the present disclosure, a storage device may include a memory device including a memory cell array, the memory cell array including a plurality of wordlines and first memory cells of a first memory page, the first memory cells of the first memory page being connected to a target wordline among the plurality of wordlines; a storage controller configured to control an operation of the memory device; a log likelihood ratio (LLR) optimization circuit configured to generate a first readout error index for data stored in the first memory cells; and an LLR set register configured to store a symmetric LLR set and an asymmetric LLR set, the symmetric LLR set including first LLR values having symmetric absolute values with respect to a reference read voltage, and the asymmetric LLR set including second LLR values having asymmetric absolute values with respect to the reference read voltage. The storage controller may include an LLR set selection circuit and a decoder. The LLR set selection circuit may be configured to receive the first readout error index from the LLR optimization circuit and select one of the symmetric LLR set and the asymmetric LLR set stored in the LLR set register based on the first readout error index. The decoder may be configured to perform error correction code (ECC) decoding by applying LLR values of the one of the symmetric LLR set and the asymmetric LLR set that is selected by the LLR set selection circuit to data read from the first memory cells. The first readout error index may include information regarding a probability of data at a first logic level stored in the first memory cells being erroneously read as data at a second logic level and information regarding a probability of data at the second logic level stored in the first memory cells being erroneously read as data at the first logic level. The second logic level may be different than the first logic level.

According to an embodiment of the present disclosure, a storage device may include a memory device including a memory cell array, the memory cell array including a plurality of wordlines and first memory cells of a first memory page, the first memory cells of the first memory page being connected to a target wordline among the plurality of wordlines; a storage controller configured to control an operation of the memory device; a log likelihood ratio (LLR) optimization circuit configured to generate a first readout error index for data stored in the first memory cells; and an LLR set register configured to store a symmetric LLR set and a first asymmetric LLR set, the symmetric LLR set including first LLR sections having symmetric widths with respect to a reference read voltage, the first asymmetric LLR set including second LLR sections having asymmetric widths with respect to the reference read voltage. The storage controller may include an LLR set selection circuit and a decoder. The LLR set selection circuit may be configured to receive the first readout error index from the LLR optimization circuit and select one of the symmetric LLR set and the first asymmetric LLR set stored in the LLR set register based on the first readout error index. The decoder may be configured to perform error correction code (ECC) decoding by applying LLR values corresponding to respective LLR sections of the one of the symmetric LLR set and the first asymmetric LLR set that is selected by the LLR set selection circuit to data read from the first memory cells. The first readout error index may include information regarding a probability of data at a first logic level stored in the first memory cells being erroneously read as data at a second logic level and information regarding a probability of data at the second logic level stored in the first memory cells being erroneously read as data at the first logic level. The second logic level may be different from the first logic level.

According to an embodiment of the present disclosure, a storage device may include a memory device including a memory cell array, the memory cell array including first memory cells of a first memory page connected to a first wordline, second memory cells of a second memory page connected to a second wordline, and a memory block including the first memory page and the second memory page; a storage controller configured to control an operation of the memory device; a log likelihood ratio (LLR) optimization circuit configured to generate a readout error index for data stored in the first memory cells; and an LLR set register configured to store a symmetric LLR set including first LLR values having symmetric absolute values with respect to a reference read voltage and an asymmetric LLR set including second LLR values having asymmetric absolute values with respect to the reference read voltage. The storage controller may include an LLR set selection circuit and a decoder. The LLR set selection circuit may be configured to receive the readout error index from the LLR optimization circuit and select one of the symmetric LLR set and the asymmetric LLR set stored in the LLR set register based on the readout error index. The decoder may be configured to perform error correction code (ECC) decoding by applying LLR values of the one of the symmetric LLR set and the asymmetric LLR set that is selected by the LLR set selection circuit to data read from the first memory cells and the second memory cells. The readout error index may include information regarding a probability of data at a first logic level stored in the first memory cells being erroneously read as data at a second logic level different from the first logic level and information regarding a probability of data at the second logic level stored in the first memory cells being erroneously read as data at the first logic level.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is a diagram illustrating a storage system according to some embodiments.

FIG. 2 is a diagram illustrating a storage device according to some embodiments.

FIG. 3 is a diagram illustrating a memory device according to some embodiments.

FIG. 4 is a diagram illustrating an example memory cell array included in the memory device of FIG. 3.

FIGS. 5 and 6 are diagrams illustrating the threshold voltage distributions of memory cells in a memory page connected to a target wordline of the memory cell array of FIG. 4.

FIG. 7 is a diagram illustrating the threshold voltage distributions of the memory cells in the memory cell array of FIG. 4 when the memory cells are QLCs.

FIG. 8 is a diagram illustrating the threshold voltage distributions of the memory cells in the memory cell array of FIG. 4 when the memory cells are QLCs and charge shift occurs due to data retention.

FIGS. 9, 10, and 11 are graphs showing the threshold voltage distributions of memory cells in the intermediate states, higher states, or lower states, respectively, of FIG. 8.

FIG. 11 is a graph showing the threshold voltage distributions of memory cells in the erase state E and the first program state P1, which are lower states.

FIG. 12 is a diagram illustrating the configuration of an ECC decoder according to some embodiments.

FIG. 13 shows a Tanner graph for explaining ECC decoding according to some embodiments.

FIG. 14 is a flowchart illustrating an operating method of a storage device according to some embodiments.

FIGS. 15 through 17 are diagrams illustrating how to perform ECC decoding by applying LLR values to data read from memory cells, according to some embodiments.

FIGS. 18 and 19 are diagrams illustrating bit mapping for programming memory cells and read levels for respective memory pages when the memory cells in the memory cell array of FIG. 4 are 4-bit QLCs.

FIG. 20 is a diagram illustrating how the LLR set selection circuit selects different LLR sets based on indices received from the LLR optimization circuit for a memory device including the QLCs shown in FIG. 18.

FIGS. 21 through 23 are diagrams illustrating how the ECC decoder performs ECC decoding by applying LLR values to data read from memory cells in the target memory page connected to the target wordline.

FIGS. 24 through 27 are diagrams illustrating how the ECC decoder according to some embodiments performs ECC decoding by applying LLR values to data read from memory cells of each memory page.

FIG. 28 is a flowchart illustrating a method of operating a storage device according to some embodiments.

FIG. 29 is a diagram illustrating a computing system including a storage device according to some embodiments.

FIG. 30 is a diagram illustrating an example of applying a storage device to a solid-state drive (SSD) system according to some embodiments.

FIG. 31 is a diagram illustrating a system including a memory device according to some embodiments.

### DETAILED DESCRIPTION

A storage device according to some embodiments will hereinafter be described with reference to the accompanying drawings.

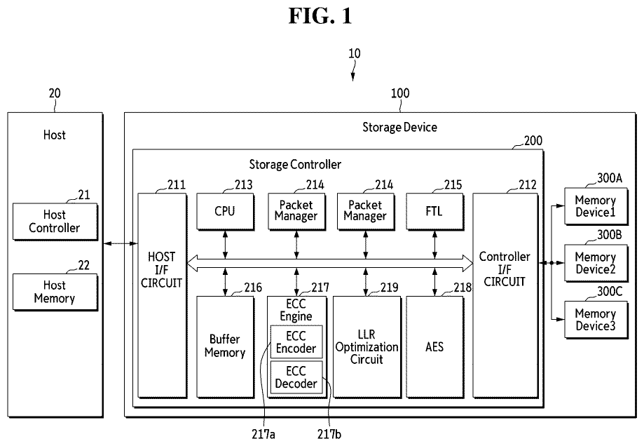

FIG. 1 is a diagram illustrating a storage system according to some embodiments.

Referring to FIG. 1, a storage system 10 may include a host 20 and a storage device 100. The storage device 100 may further include a storage controller 200 and memory devices 300A, 300B, and 300C. The host 20 may include a host controller 21 and a host memory 22. The host memory 22 may function as a buffer memory for temporarily storing data to be transmitted to the storage device 100 or data transmitted from the storage device 100.

The storage device 100 may include storage media for storing data according to requests from the host 20. For example, the storage device 100 may include at least one of a solid-state drive (SSD), embedded memory, or detachable external memory. When the storage device 100 is an SSD, it may conform to the Non-Volatile Memory express (NVMe) standard. When the storage device 100 is embedded memory or external memory, it may conform to the Universal Flash Storage (UFS) or embedded Multi-Media Card (eMMC) standard. The host 20 and the storage device 100 may generate and transmit packets according to the respective adopted standard protocols.

For example, each of the memory devices 300A, 300B, and 300C of the storage device 100 may include flash memory. The flash memory may include a 2D NAND memory array or a 3D (or vertical) NAND (VNAND) memory array. In another example, the storage device 100 may include various other types of nonvolatile memory devices. For example, the storage device 100 may include magnetic random-access memory (MRAM), spin-transfer torque MRAM, conductive bridging random-access memory (CBRAM), ferroelectric random-access memory (FeRAM), phase random-access memory (PRAM), resistive random-access memory (RRAM), and other various types of memories. In the following description, each of the memory devices 300A, 300B, and 300C is exemplified as NAND flash memory.

However, the present disclosure is not limited to this, and in some embodiments, at least one of the memory devices 300A, 300B, and 300C may be a volatile memory device that stores a plurality of bits of data in each single memory cell. For example, at least one of the memory devices 300A, 300B, and 300C may be dynamic random access memory (DRAM) that includes at least one memory cell capable of storing multiple bits of data, such as a multi-level cell (MLC), triple-level cell (TLC), or quadruple-level cell (QLC).

The host controller 21 and the host memory 22 may be implemented as separate semiconductor chips. Alternatively, the host controller 21 and host memory 22 may be integrated into the same semiconductor chip. The host controller 21 may be one of multiple modules provided in an application processor, and the application processor may be implemented as a system-on-chip (SoC). The host memory 22 may be an embedded memory provided within the application processor or a nonvolatile memory or memory module disposed outside the application processor.

The host controller 21 may manage operations of storing data (e.g., write data) from the host memory 22 into the memory devices 300A, 300B, and 300C or storing data (e.g., read data) from the memory devices 300A, 300B, and 300C into the host memory 22.

The storage controller 200 may include a host interface circuit 211, a controller interface circuit 212, and a central processing unit (CPU) 213. The storage controller 200 may also include a flash translation layer 215, a packet manager 214, a buffer memory 216, an error correction code (ECC) engine 217, a log likelihood ratio (LLR) optimization (or improvement) circuit 219, and an advanced encryption standard (AES) engine 218. The storage controller 200 may further include a working memory into which the flash translation layer 215 is loaded. The CPU 213 may execute the flash translation layer 215 to control data write and read operations on the memory devices 300A, 300B, and 300C.

The host interface circuit 211 may transmit and receive packets to and from the host 20. Packets transmitted from the host 20 to the host interface circuit 211 may include commands or data to be written to the memory devices 300A, 300B, and 300C. Packets transmitted from the host interface circuit 211 to the host 20 may include responses to commands or data read from the memory devices 300A, 300B, and 300C. The controller interface circuit 212 may transmit data to be written to the memory devices 300A, 300B, and 300C or receive data read from the memory devices 300A, 300B, and 300C. The controller interface circuit 212 may be implemented to comply with standard protocols such as Toggle or ONFI.

The flash translation layer 215 may perform various functions such as address mapping, wear-leveling, and garbage collection. Address mapping converts logical addresses received from the host 20 into physical addresses used for actually storing data in the memory devices 300A, 300B, and 300C. Wear-leveling ensures uniform usage of blocks within the memory devices 300A, 300B, and 300C to limit and/or prevent excessive degradation of particular blocks, and may be implemented through a firmware technique that balances erase counts of physical blocks. Garbage collection secures available capacity within the memory devices 300A, 300B, and 300C by copying valid data of a block to a new block and then erasing the original block.

The packet manager 214 may generate packets according to the protocol of the interface agreed upon with the host 20 or parse various information from packets received from the host 20. Additionally, the buffer memory 216 may temporarily store data to be written to the memory devices 300A, 300B, and 300C or data read from the memory devices 300A, 300B, and 300C. The buffer memory 216 may be a component provided within the storage controller 200 but may also be disposed outside the storage controller 200.

The ECC engine 217 may perform error detection and correction for read data read from the memory devices 300A, 300B, and 300C. Specifically, the ECC engine 217 may generate parity bits for write data to be written to the memory devices 300A, 300B, and 300C. The generated parity bits may be stored in the memory devices 300A, 300B, and 300C along with the write data. During data read operations from the memory devices 300A, 300B, and 300C, the ECC engine 217 may correct errors in the read data using parity bits read from the memory devices 300A, 300B, and 300C and output the error-corrected read data.

The ECC engine 217 may include an ECC encoder 217a and an ECC decoder 217b. The ECC encoder 217a may perform ECC encoding for data to be stored in the memory devices 300A, 300B, and 300C, and the ECC decoder 217b may perform ECC decoding for data read from the memory devices 300A, 300B, and 300C.

During a read operation targeting the memory cells of a memory page connected to a target wordline among a plurality of wordlines of any one of the memory devices 300A, 300B, and 300C, the ECC decoder 520 may perform ECC decoding by applying LLR values, which are one of the ECC parameter values, to the data read from the corresponding memory cells.

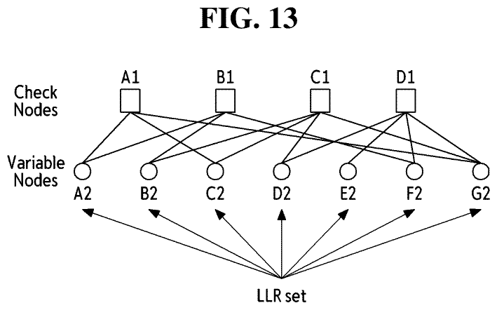

At this time, the ECC decoder 217b may select one of a plurality of LLR sets stored in the storage device 100 based on retention information for each of the memory cells, information regarding the memory page to which the memory cells belong, information regarding the number of bits per memory cell for each of the memory cells, and information regarding readout errors (or readout failures) of the data stored in each of the memory cells. The ECC decoder 217b may perform ECC decoding by applying the LLR values included in the selected LLR set to the data read from the memory cells. The method of performing ECC decoding by applying LLR values to the data read from the memory cells will be described later with reference to FIG. 13 and others.

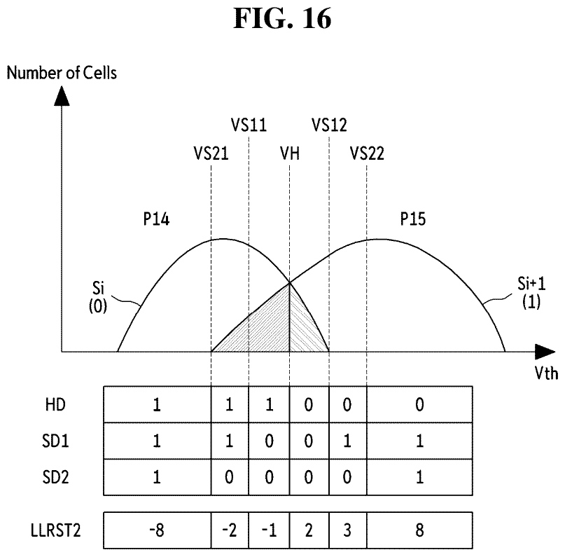

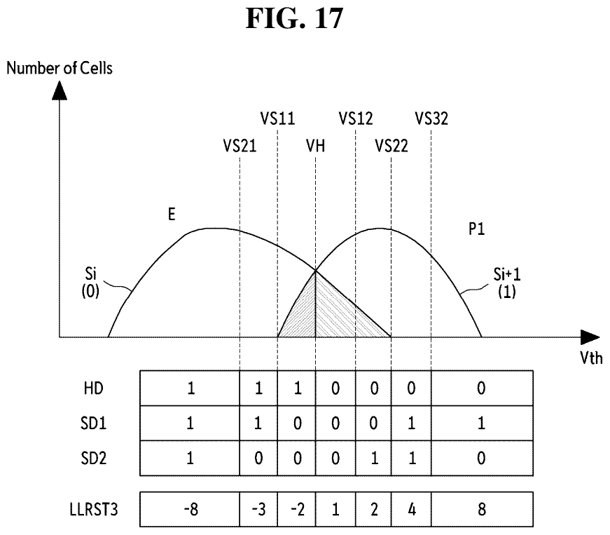

The plurality of LLR sets stored in the storage device 100 may include at least one symmetric LLR set, which includes LLR values having symmetric absolute values with respect to a reference read voltage, and at least one asymmetric LLR set, which includes LLR values having asymmetric absolute values with respect to the reference read voltage. The symmetric and asymmetric LLR sets will be described later with reference to FIGS. 16 and 17 and others.

The LLR optimization circuit 219 may generate information regarding readout errors (or readout failures) of the data stored in each memory cell during a read operation targeting the memory cells of a memory page connected to a target wordline among a plurality of wordlines of one of the memory devices 300A, 300B, and 300C, for example, the memory device 300A, and may transmit the generated information regarding readout errors to the ECC decoder 217b.

Additionally, the LLR optimization circuit 219 may transmit the retention information for each of the memory cells, the information regarding the memory page to which the memory cells belong, and the information regarding the number of bits per memory cell for each of the memory cells to the ECC decoder 217b.

The retention information for each of the memory cells may include information regarding the extent of degradation of the characteristics of the memory cells since data storage.

The information regarding the memory page to which the memory cells belong may include, for example, whether the memory page to which the memory cells belong is a most significant bit (MSB) page, an upper significant bit (USB) page, an extra significant bit (ESB) page, or a least significant bit (LSB) page, assuming that the memory cells are QLCs.

The information regarding the number of bits per memory cell for each of the memory cells may include information regarding whether the corresponding memory cell is an SLC, MLC, TLC, or QLC, and how many bits are stored in the corresponding memory cell.

The AES engine 218 may perform at least one of an encryption operation or a decryption operation for data input to the storage controller 200 using a symmetric-key algorithm.

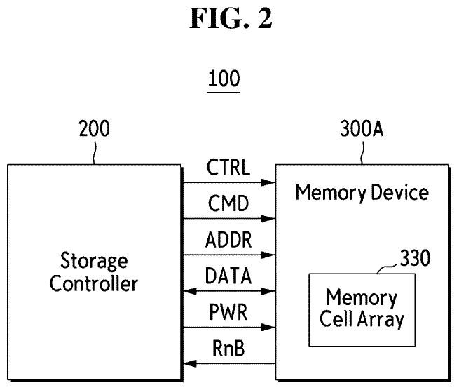

FIG. 2 is a diagram illustrating a storage device according to some embodiments.

Referring to FIG. 2, the storage device 100 may include the storage controller 200 and the memory device 300A. FIG. 2 illustrates, as an example, only the memory device 300A among the memory devices 300A, 300B, and 300C included in the storage system 10 of FIG. 1. The following description of the memory device 300A is also applicable to the other memory devices 300B and 300C.

The storage controller 200 may perform a control operation for the memory device 300A. Specifically, the storage controller 200 may generate an address ADDR, a command CMD, and a control signal CTRL for controlling the memory device 300A. The storage controller 200 may control program (or write), read, and erase (or delete) operations for the memory device 300A by providing the address ADDR, the command CMD, and the control signal CTRL to the memory device 300A. Additionally, data DATA for the program operation and read data DATA may be transmitted and received between the storage controller 200 and the memory device 300A.

In some embodiments, the storage controller 200 may generate the control signal CTRL, the command CMD, the address ADDR, and the data DATA for controlling the operation of the memory device 300A, and may transmit the generated control signal CTRL, command CMD, address ADDR, and data DATA to the memory device 300A. The memory device 300A may transmit a read/busy signal RnB to the storage controller 200 for indicating a state of the memory device 300A to the storage controller 200, such as a busy state or ready state. For example, when the memory device 300A is in the busy state, the memory device 300A may be unable to receive the control signal CTRL, command CMD, or address ADDR from the storage controller 200 or exchange data DATA with the storage controller 200. When the memory device 300A is in the ready state, the memory device 300A may be able to receive the control signal CTRL, command CMD, and address ADDR from the storage controller 200, and the memory device 300A may be able to exchange data DATA with the storage controller 200.

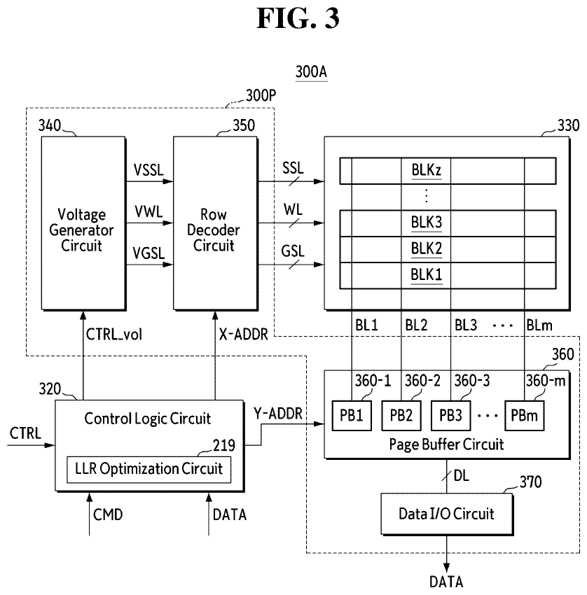

FIG. 3 is a diagram illustrating a memory device according to some embodiments.

Referring to FIG. 3, the memory device 300A may include a control logic circuit 320, a peripheral circuit 300P, and a memory cell array 330. The memory device 300A may further include column logic, a pre-decoder, a temperature sensor, a command decoder, and an address decoder.

The control logic circuit 320 may generally control various operations within the memory device 300A. The control logic circuit 320 may output various control signals in response to a command CMD and/or addresses ADDR received from the storage controller 200. For example, the control logic circuit 320 may output a voltage control signal CTRL_vol, a row address X-ADDR, and a column address Y-ADDR. The voltage control signal CTRL_vol may include a program signal or an erase signal.

The control logic circuit 320 may include the LLR optimization circuit 219. That is, the LLR optimization circuit 219 described with reference to FIG. 1 may be included in the storage controller 200, as illustrated in FIG. 1. Alternatively, in some embodiments, the LLR optimization circuit 219 may be included in the control logic circuit 320 of the memory device 300A.

The memory cell array 330 may include a plurality of memory blocks BLK1 through BLKz (where z is an integer of 2 or greater), and each of the memory blocks BLK1 through BLKz may include a plurality of memory cells. The memory cell array 330 may be connected to the page buffer circuit 360 through bitlines BL1 through BLm (where m is an integer of 2 or greater) and may be connected to the row decoder circuit 350 through wordlines WL, string select lines SSL, and ground select lines GSL.

In one example embodiment, the memory cell array 330 may include a three-dimensional (3D) memory cell array, and the 3D memory cell array may include a plurality of NAND strings. Each of the NAND strings may include memory cells connected to respective wordlines WL vertically stacked on a substrate. In another example embodiment, the memory cell array 330 may include a two-dimensional (2D) memory cell array, and the 2D memory cell array may include a plurality of NAND strings disposed along row and column directions.

The memory cells included in the memory cell array 330 may each store at least one data bit. For example, the memory cells may be SLCs or MLCs such as TLCs or QLCs, and may, in some embodiments, be implemented as MLCs capable of storing five or more bits.

The peripheral circuit 300P may include a page buffer circuit 360, a voltage generation circuit 340, a row decoder circuit 350, and a data input/output circuit 370.

The page buffer circuit 360 may include a plurality of page buffers PB1 through PBm (where m is an integer of 2 or greater), and the page buffers PB1 through PBm may be connected to the memory cells via a plurality of bitlines BL1 through BLm, respectively. The page buffer circuit 360 may select at least one of the bitlines BL1 through BLm in response to a column address Y-ADDR. The page buffer circuit 360 may operate as a write driver or a sense amplifier depending on the operation mode. For example, during a program operation, the page buffer circuit 360 may apply a bitline voltage corresponding to data to be programmed to the selected bitline. During a read operation, the page buffer circuit 360 may sense the current or voltage of the selected bitline to detect the data stored in the memory cells.

The voltage generation circuit 340 may generate various types of voltages for performing program, read, and erase operations on the memory cell array 330 based on the voltage control signal CTRL_vol. For example, the voltage generation circuit 340 may generate wordline voltages VWL such as program voltage, read voltage, program verify voltage, and erase voltage for driving the wordlines WL. Additionally, the voltage generation circuit 340 may generate a string select line voltage VSSL for driving the string select lines SSL and a ground select line voltage VGSL for driving the ground select lines GSL. Here, the string select line voltage VSSL may be a string select voltage, e.g., an on-voltage or an off-voltage. Furthermore, the ground select line voltage VGSL may be a ground select voltage, e.g., an on-voltage or an off-voltage.

The row decoder circuit 350 may select one of the wordlines WL and one of the string select lines SSL in response to a row address X-ADDR. For example, during a program operation, the row decoder circuit 350 may apply a program voltage and a program verify voltage to the selected wordline WL and a pass voltage to the unselected wordlines WL. During a read operation, the row decoder circuit 350 may apply a read voltage to the selected wordline WL and a pass voltage to the unselected wordlines WL.

Additionally, during an erase operation, the row decoder circuit 350 may apply an erase voltage (e.g., OV) to the wordlines WL and may float the string select lines SSL and the ground select lines GSL.

The data input/output circuit 370 may be connected to the page buffer circuit 360 via a plurality of data lines DL. During a program operation, the data input/output circuit 370 may receive program data DATA from the storage controller 200 illustrated in FIG. 2 and provide the program data DATA to the page buffer circuit 360 based on the column address Y-ADDR provided from the control logic circuit 320. During a read operation, the data input/output circuit 370 may provide read data DATA stored in the page buffer circuit 360 to the storage controller 200 based on the column address Y-ADDR provided from the control logic circuit 320.

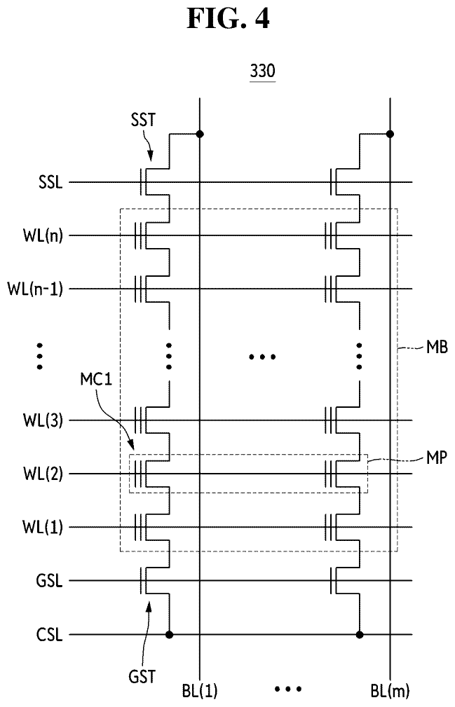

FIG. 4 is a diagram illustrating an example memory cell array included in the memory device of FIG. 3.

Referring to FIG. 4, the memory cell array 330 may include string select transistors SST, ground select transistors GST, and memory cells MC1. The string select transistors SST may be connected to a plurality of bitlines BL(1) through BL(m), and the ground select transistors GST may be connected to a common source line CSL. Memory cells MC1 arranged in the same column may be connected in series between one of the bitlines BL(1) through BL(m) and the common source line CSL, and memory cells MC1 arranged in the same row may be commonly connected to one of a plurality of wordlines WL(1) through WL(n). In other words, the memory cells MC1 may be connected in series between the string select transistors SST and the ground select transistors GST, and between the string select lines SSL and the ground select lines GSL, and 16, 32, or 64 wordlines may be arranged between the string select transistors SST and the ground select lines GSL.

The string select transistors SST may be connected to the string select lines SSL and controlled based on the voltage level applied from the string select lines SSL. The ground select transistors GST may be connected to the ground select lines GSL and controlled based on the voltage level applied from the ground select lines GSL. The memory cells MC1 may be controlled based on the voltage level applied to the wordlines WL(1) through WL(n).

A NAND flash memory device including the memory cell array 330 may perform program and read operations in units of memory pages MP and may perform erase operations in units of memory blocks MB. In some embodiments, the page buffers PB1 through PBm illustrated in FIG. 3 may each be connected to one even-numbered bitline and one odd-numbered bitline. In this case, even-numbered bitlines may form even pages, odd-numbered bitlines may form odd pages, and program operations for the memory cells MC1 may be sequentially performed alternately for even and odd pages.

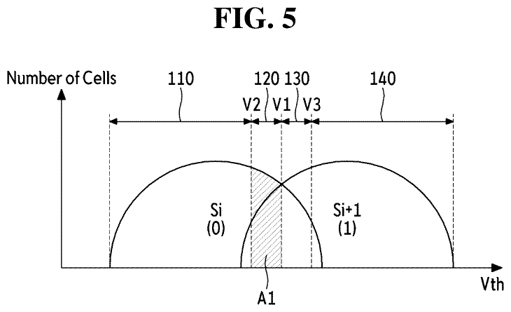

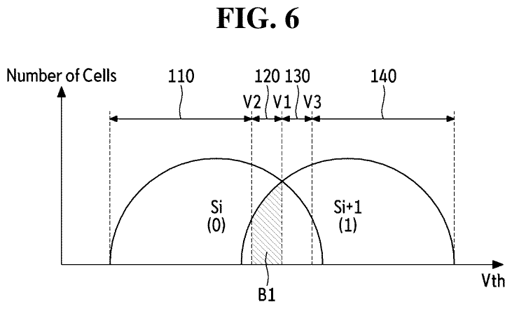

FIGS. 5 and 6 are diagrams illustrating the threshold voltage distributions of memory cells in a memory page connected to a target wordline of the memory cell array of FIG. 4.

Referring to FIGS. 5 and 6, the memory device 300A may have threshold voltage (Vth) distributions. For example, assuming that the wordline WL(2) in FIG. 4 is the target wordline, the threshold voltage distributions of memory cells MC1 in a memory page MP connected to the wordline WL(2) may appear as shown in the graphs of FIGS. 5 and 6.

The threshold voltage distributions of the memory cells MC1 may include a first state Si corresponding to data “0” and a second state Si+1 corresponding to data “1.” In other words, memory cells MC1 with a threshold voltage distribution in the first state Si and memory cells MC1 with a threshold voltage distribution in the second state Si+1 may store data with different logic levels (e.g., data “0” and data “1”). In the following description, data “0” is assumed to be a first logic level, and data “1” is assumed to be a second logic level.

When the memory device 300A performs a hard-decision read operation and a soft-decision read operation, the threshold voltage distributions of the memory cells MC1 may be divided into four sections 110, 120, 130, and 140 based on three voltages V1, V2, and V3. Here, the voltage V1 may be a hard-decision read voltage, and the voltages V2 and V3 may be soft-decision read voltages. The hard- and soft-decision read operations will be described later with reference to FIG. 16 and others.

Since it is difficult to optimize the LLR value for each individual memory cell MC1, the threshold voltage distributions of the memory cells MC1 may be divided into the four sections 110, 120, 130, and 140, and the memory cells MC1 within each section may be assigned the same LLR value.

For example, an LLR value LLR1 for the section 120 may be obtained based on Equation 1 below.

$$LLR 1 = log ( \frac{A 1}{B 1} ) \qquad [ Equation 1 ]$$

In Equation 1, A1 corresponds to region A1 in FIG. 5, and B1 corresponds to region B1 in FIG. 6. A1 may indicate the probability that data stored in the memory cells MC1 is “0,” and may represent the number of memory cells MC1 corresponding to data “0” among the memory cells MC1 with a threshold voltage between the voltages V1 and V2. B1 may indicate the probability that the data stored in the memory cells MC1 is “1,” and may represent the number of memory cells MC1 corresponding to data “1” among the memory cells MC1 with a threshold voltage between the voltages V1 and V2. In this manner, LLR values for the other sections 110, 130, and 140 may also be obtained. Accordingly, one of four LLR values may be assigned to each memory cell MC1 in the memory device 300A, and these LLR values may be used for error correction when reading data from the memory device 300A using a low-density parity check (LDPC) code.

LLR values are logarithms of the ratios of probabilities that the data stored in the memory cells MC1 corresponds to “1” or “0.” During the design/manufacture of the memory device 300A, initial threshold voltage distributions for the memory cells MC1 may be assumed, and initial LLR values may be determined based on these assumed initial distributions. However, due to the degradation of the characteristics of the memory cells MC1, the initial threshold voltage distributions may be altered or distorted. When the initial threshold voltage distributions are altered or distorted, using the initial LLR values may cause error correction to be inaccurate.

Therefore, it may be advantageous to improve or optimize the LLR values by applying different LLR values to the memory cells MC1 based on retention information for the memory cells MC1, information regarding the memory page to which the memory cells MC1 belong, information regarding the number of bits per memory cell, and information regarding readout errors (or readout failures) of the data stored in the memory cells MC1. The optimized LLR values may then need to be applied during ECC decoding of the data read from the memory cells MC1.

FIGS. 5 and 6 show an example in which the threshold voltage distributions of the memory cells MC1 are divided into four sections 110, 120, 130, and 140 based on three voltages V1, V2, and V3, but the present disclosure is not limited thereto. Alternatively, if additional soft-decision read voltages are further provided in addition to the voltages V2 and V3, the threshold voltage distributions may be divided into five or more sections, and LLR values may be assigned to memory cells MC1 in each of these sections.

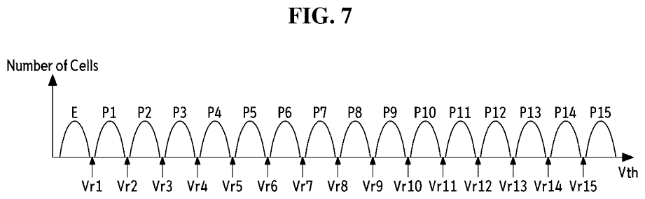

FIG. 7 is a diagram illustrating the threshold voltage distributions of the memory cells in the memory cell array of FIG. 4 when the memory cells are QLCs.

Referring to FIG. 7, when the memory cells MC1 included in the memory device 300A are QLCs, the memory cells MC1 may be in one of an erase state E or first through fifteenth program states P1 through P15.

A first read voltage Vr1 corresponds to the voltage level between the threshold voltage distributions of memory cells MC1 in the erase state E and the threshold voltage distributions of memory cells MC1 in the first program state P1. Similarly, each of second through fifteenth read voltages Vr2 through Vr15 corresponds to the voltage level between the threshold voltage distributions of memory cells MC1 in the respective pair of adjacent program states.

In one embodiment, when the first read voltage Vr1 is applied and memory cells MC1 are turned on, the memory cells MC1 may be identified as storing data “0.” Conversely, if the memory cells MC1 are turned off, the memory cells MC1 may be identified as storing data “1.” Specifically, memory cells MC1 that are turned on with current flowing in their gate electrodes in response to the first read voltage Vr1 being applied may be defined as being in an on-cell state, and memory cells MC1 that are turned off with no current flowing in their gate electrodes in response to the first read voltage Vr1 being applied may be defined as being in an off-cell state. However, the embodiments are not limited to this. Alternatively, in other embodiments, when memory cells MC1 are turned on, the memory cells MC1 may be identified as storing data “1,” and when the memory cells MC1 are turned off, the memory cells MC1 may be identified as storing data “0.” The assignment of logical levels to data may vary from embodiment to embodiment.

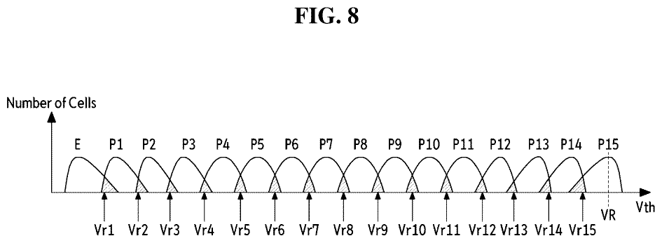

FIG. 8 is a diagram illustrating the threshold voltage distributions of the memory cells in the memory cell array of FIG. 4 when the memory cells are QLCs and charge shift occurs due to data retention.

Referring to FIG. 8, memory cells MC1 programmed into the erase state E or the first through fifteenth program states P1 through P15 may exhibit altered distributions depending on the readout environment.

Compared to SLCs, MLCs (e.g., TLCs or QLCs) are capable of storing multiple data bits and may have narrower spacing between threshold voltage distributions. Thus, even small changes in the threshold voltage Vth may cause significant issues in MLCs.

For example, as shown in FIG. 8, overlapping regions (e.g., hatched areas) may be formed between the threshold voltage distributions of memory cells MC1 corresponding to different states. In FIG. 8, memory cells in the hatched areas may experience readout errors, leading to reduced reliability of the memory device 300A.

For example, when a readout operation is performed using the first read voltage Vr1, memory cells MC in the hatched areas may be misjudged as being in the erase state E due to a reduction in threshold voltage Vth, even though they have been programmed to the first program state P1. Consequently, readout errors may occur, reducing the reliability of the memory device 300A.

Furthermore, over time, after data is stored in the memory cells MC1, charge shift due to data retention may occur. For example, as shown in FIG. 8, memory cells MC1 in higher states (e.g., thirteenth through fifteenth program states P13 through P15) may experience charge loss due to data retention, causing their threshold voltage distributions to shift to the left (e.g., toward a lower threshold voltage Vth). Conversely, memory cells MC1 in lower states (e.g., the erase state E or the first and second program states P1 and P2) may experience charge gain due to data retention, causing their threshold voltage distributions to shift to the right (e.g., toward a higher threshold voltage Vth).

As a result, as shown in FIG. 8, the threshold voltage distributions for some program states (e.g., the third through twelfth program states P3 through P12, hereinafter referred to as intermediate states) may appear symmetrical such that the threshold voltage distributions do not shift either to the left or to the right, but the threshold voltage distributions of the higher states (e.g., the thirteenth through fifteenth program states P13 through P15) and the lower states (e.g., the erase state E and the first and second program states P1 and P2) may appear asymmetrical in the overlapping regions (e.g., the hatched areas in FIG. 8) between the threshold voltage distributions of memory cells MC1 corresponding to different states.

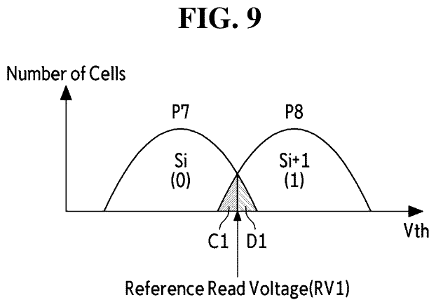

The threshold voltage distributions of memory cells in intermediate states, higher states, or lower states will hereinafter be described with reference to FIGS. 9 through 11.

FIGS. 9, 10, and 11 are graphs showing the threshold voltage distributions of memory cells in the intermediate states, higher states, or lower states, respectively, of FIG. 8.

Specifically, FIG. 9 is a graph showing the threshold voltage distributions of memory cells in the seventh and eighth program states P7 and P8, which are intermediate states. Referring to FIGS. 8 and 9, the memory cells in the seventh program state P7 may store data “0,” and the memory cells in the eighth program state P8 may store data “1.” Additionally, a reference read voltage RV1 may correspond to the voltage corresponding to a hard-decision read operation.

Among the memory cells in the seventh program state P7, those with a threshold voltage Vth lower than the reference read voltage RV1 may be in an on-cell state when the reference read voltage RV1 is applied, and may be read as storing data “0.” Similarly, among the memory cells in the eighth program state P8, those with a threshold voltage Vth higher than the reference read voltage RV1 may be in an off-cell state when the reference read voltage RV1 is applied, and may be read as storing data “1.”

However, as the spacing between the threshold voltage distributions of the memory cells narrows, overlapping regions (including regions C1 and D1) may occur between the threshold voltage distributions of the memory cells in the seventh and eighth program states P7 and P8.

Memory cells in region D1 may correspond to the seventh program state P7 and store data “0.” However, since these memory cells have a threshold voltage Vth higher than the reference read voltage RV1, they may be erroneously read as being in an off-cell state, with data “1” stored.

Similarly, memory cells in region C1 may correspond to the eighth program state P8 and store data “1.” However, since these memory cells have a threshold voltage Vth lower than the reference read voltage RV1, they may be erroneously read as being in an on-cell state, with data “0” stored.

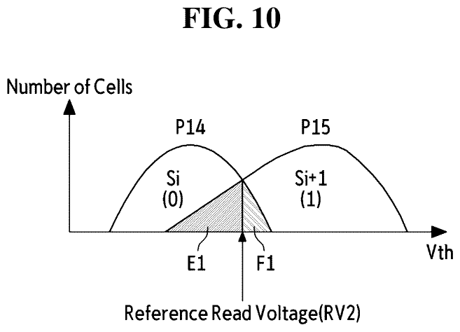

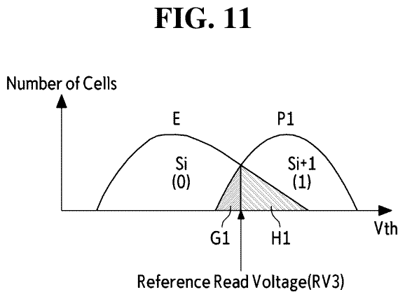

Since the seventh and eighth program states P7 and P8 are intermediate states, the degree of charge shift caused by data retention may not be significant compared to higher states (refer to FIG. 10) or lower states (refer to FIG. 11). Accordingly, the threshold voltage distributions for the seventh and eighth program states P7 and P8 may not exhibit a directional shift. Thus, the sizes of regions C1 and D1 may appear similar, resulting in a symmetric shape.

Thus, the probability of readout errors occurring during a read operation for the memory cells in the seventh program state P7 may be similar to the probability of readout errors occurring during a read operation for the memory cells in the eighth program state P8.

FIG. 10 is a graph showing the threshold voltage distributions of memory cells in the fourteenth and fifteenth program states P14 and P15, which are higher states. At this time, the memory cells in the fourteenth program state P14 may store data “0,” and the memory cells in the fifteenth program state P15 may store data “1.” Additionally, a reference read voltage RV2 may correspond to the voltage corresponding to a hard-decision read operation.

Among the memory cells in the fourteenth program state P14, those with a threshold voltage lower than the reference read voltage RV2 may be in an on-cell state when the reference read voltage RV2 is applied, and may be read as storing data “0.” Similarly, among the memory cells in the fifteenth program state P15, those with a threshold voltage higher than the reference read voltage RV2 may be in an off-cell state when the reference read voltage RV2 is applied, and may be read as storing data “1.”

However, as the spacing between the threshold voltage distributions of the memory cells narrows, overlapping regions (including regions E1 and F1) may occur between the threshold voltage distributions of the memory cells in the fourteenth and fifteenth program states P14 and P15.

Memory cells in region F1 may correspond to the fourteenth program state P14 and store data “0.” However, since these memory cells have a threshold voltage Vth higher than the reference read voltage RV2, they may be erroneously read as being in an off-cell state, with data “1” stored.

Similarly, memory cells in region E1 may correspond to the fifteenth program state P15 and store data “1.” However, since these memory cells have a threshold voltage Vth lower than the reference read voltage RV2, they may be erroneously read as being in an on-cell state, with data “0” stored.

Since the fourteenth and fifteenth program states P14 and P15 are higher states, charge loss may occur due to data retention. Specifically, the threshold voltage distribution for the fifteenth program state P15 may shift further to the left (e.g., toward a lower threshold voltage Vth) compared to the threshold voltage distribution for the fourteenth program state P14. Thus, region E1 may be larger than region F1, resulting in an asymmetric shape.

As a result, the probability of readout errors occurring during a read operation for the memory cells in the fifteenth program state P15 may be greater than the probability of readout errors occurring during a read operation for the memory cells in the fourteenth program state P14.

FIG. 11 is a graph showing the threshold voltage distributions of memory cells in the erase state E and the first program state P1, which are lower states. Referring to FIGS. 8 and 11, the memory cells in the erase state E may store data “0,” and the memory cells in the first program state P1 may store data “1.” Additionally, a reference read voltage RV3 may correspond to the voltage used in a hard-decision read operation.

Among the memory cells in the erase state E, those with a threshold voltage Vth lower than the reference read voltage RV3 may be in an on-cell state when the reference read voltage RV3 is applied, and may be read as storing data “0.” Similarly, among the memory cells in the first program state P1, those with a threshold voltage Vth higher than the reference read voltage RV3 may be in an off-cell state when the reference read voltage RV3 is applied, and may be read as storing data “1.”

However, as the spacing between the threshold voltage distributions of the memory cells narrows, overlapping regions (including regions G1 and H1) may occur between the threshold voltage distributions of the memory cells in the erase state E and the first program state P1.

Memory cells in region H1 may correspond to the erase state E and store data “0.” However, since these memory cells have a threshold voltage Vth higher than the reference read voltage RV3, they may be erroneously read as being in an off-cell state, with data “1” stored.

Similarly, memory cells in region G1 may correspond to the first program state P1 and store data “1.” However, since these memory cells have a threshold voltage Vth lower than the reference read voltage RV3, they may be erroneously read as being in an on-cell state, with data “0” stored.

Since the erase state E and the first program state P1 are lower states, charge gain may occur due to data retention. Specifically, the threshold voltage distribution for the erase state E may shift further to the right (e.g., toward a higher threshold voltage Vth) compared to the threshold voltage distribution for the first program state P1. Thus, region H1 may be larger than region G1, resulting in an asymmetric shape.

As a result, the probability of readout errors occurring during a read operation for the memory cells in the erase state E may be greater than the probability of readout errors occurring during a read operation for the memory cells in the first program state P1.

When charge shift occurs due to data retention, the probability of data with the first logic level being erroneously read as data with the second logic level and the probability of data with the second logic level being erroneously read as data with the first logic level may differ. Therefore, to reduce or minimize data readout errors during ECC decoding, it may be advantageous to improve or optimize the LLR values applied to the memory cells by assigning different LLR values while considering the respective probabilities of such readout errors.

In some embodiments, if the deviation between the probability of data with the first logic level being erroneously read as data with the second logic level and the probability of data with the second logic level being erroneously read as data with the first logic level for memory cells in a target memory page connected to a target wordline exceeds a desired and/or alternatively predetermined threshold, the storage controller 200 may apply LLR values included in an asymmetric LLR set during ECC decoding for the target memory page. Conversely, if this deviation is smaller than a desired and/or alternatively predetermined threshold, the storage controller 200 may apply LLR values included in a symmetric LLR set during ECC decoding for the target memory page.

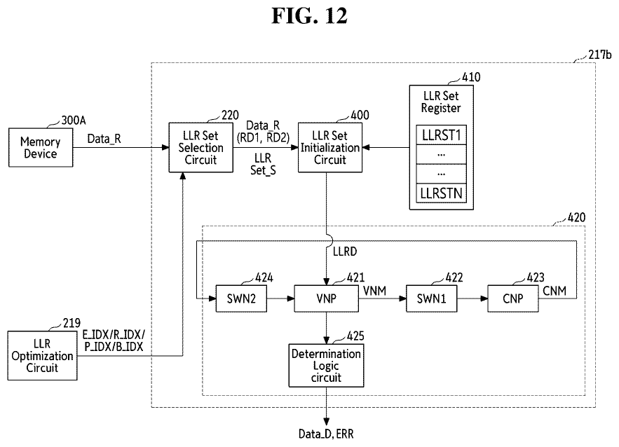

FIG. 12 is a diagram illustrating the configuration of an ECC decoder according to some embodiments. FIG. 13 shows a Tanner graph for explaining ECC decoding according to some embodiments.

The ECC decoding operation of the ECC decoder according to some embodiments will hereinafter be described with reference to FIGS. 12 and 13.

The memory device 300A may perform a read operation, including a hard-decision read operation and/or a soft-decision read operation, for a target memory page. The target memory page refers to a single memory page to be read, among a plurality of memory pages is connected to a target wordline. The hard-decision read operation involves applying a reference read voltage to the target wordline and reading hard-decision data from the memory cells connected to the target wordline based on the on/off states of the memory cells. The ECC decoder 217b of the storage controller 200 may perform hard-decision error correction using only the hard-decision data and error correction code (e.g., an LDPC code).

Additionally, the soft-decision read operation involves applying a plurality of offset read voltages with a uniform interval therebetween to the target wordline and reading soft-decision data that includes reliability information for the hard-decision data from the memory cells connected to the target wordline. The ECC decoder 217b may perform soft-decision error correction using the hard-decision data, the error correction code (e.g., an LDPC code), and the reliability information for the hard-decision data.

Referring to FIG. 12, the ECC decoder 217b may include an LLR set selection circuit 220, an LLR set initialization circuit 400, an LLR set register 410, and a decoder 420.

The LLR set selection circuit 220 may store data Data_R read from the memory page connected to the target wordline and provide the stored read data Data_R to the LLR set initialization circuit 400. Additionally, the LLR set selection circuit 220 may receive a read error index E_IDX, a retention index R_IDX, a page index P_IDX, and a bits-per-cell index B_IDX from the LLR optimization circuit 219.

The read error index E_IDX may include information regarding the probability that data stored in the memory cells of the memory page connected to the target wordline with the first logic level being erroneously read as data with the second logic level, and the probability that data stored in the same memory cells with the second logic level being erroneously read as data with the first logic level.

The retention index R_IDX may include retention information for the memory cells in the memory page connected to the target wordline, that is, information regarding the extent of degradation of the characteristics of the memory cells since data storage. For example, the retention index R_IDX may include information on whether the threshold voltage distributions of the memory cells have undergone charge loss, charge gain, or the degree of such charge shift.

The page index P_IDX may include information regarding the memory page connected to the target wordline, such as whether the memory page is an MSB page, USB page, ESB page, or LSB page.

The bits-per-cell index B_IDX may include information regarding the number of bits per memory cell for each of the memory cells in the memory page connected to the target wordline, that is, how many bits are stored in each single memory cell.

The LLR set selection circuit 220 may store data read from the memory page connected to the target wordline as first read data RD1 using a reference read voltage, and store data read using offset read voltages different from the reference read voltage as second read data RD2. The LLR set selection circuit 220 may also provide the first read data RD1 and the second read data RD2 to the LLR set initialization circuit 400.

The LLR set selection circuit 220 may select one of the LLR sets stored in the LLR set register 410, e.g., an LLR set LLR Set_S, based on at least one of the read error index E_IDX, retention index R_IDX, page index P_IDX, or bits-per-cell index B_IDX received from the LLR optimization circuit 219. The LLR set selection circuit 220 may provide information regarding the selected LLR set LLR Set_S to the LLR set initialization circuit 400.

The LLR set register 410 may include N LLR sets LLRST1 through LLRSTN (where N is an integer of 2 or greater). Each of the LLR sets LLRST1 through LLRSTN may include a plurality of LLR values. Among the LLR sets LLRST1 through LLRSTN, at least one LLR set may include LLR values having symmetric absolute values with respect to a reference voltage level, while at least one other LLR set may include LLR values having asymmetric absolute values with respect to the reference voltage level. An LLR set with LLR values having symmetric absolute values with respect to the reference voltage level may be referred to as a symmetric LLR set, whereas an LLR set with LLR values having asymmetric absolute values may be referred to as an asymmetric LLR set.

The LLR set selection circuit 220 may select a symmetric LLR set or an asymmetric LLR set from among the LLR sets LLRST1 through LLRSTN stored in the LLR set register 410 based on at least one of the read error index E_IDX, retention index R_IDX, page index P_IDX, or bits-per-cell index B_IDX received from the LLR optimization circuit 219.

For example, if the deviation between the probability of data stored in the memory cells of the memory page connected to the target wordline with the first logic level being erroneously read as data with the second logic level, and the probability of data stored in the same memory cells with the second logic level being erroneously read as data with the first logic level, exceeds a desired and/or alternatively predetermined threshold, the LLR set selection circuit 220 may select an asymmetric LLR set.

Conversely, if the deviation between the probability of data stored in the memory cells of the memory page connected to the target wordline with the first logic level being erroneously read as data with the second logic level, and the probability of data stored in the same memory cells with the second logic level being erroneously read as data with the first logic level, is smaller than the desired and/or alternatively predetermined threshold, the LLR set selection circuit 220 may select a symmetric LLR set.

During the soft-decision decoding of the second read data RD2, the LLR set initialization circuit 400 may map the LLR values of the selected LLR set LLR Set_S to the read data Data_R provided from the LLR set selection circuit 220 based on the information LLR Set_S regarding the selected LLR set, and output LLR data LLRD.

The decoder 420 may update the values of variable nodes and check nodes by perform a node operation based on the LLR data LLRD, and may output decoded data Data_D or a read error message ERR by performing decoding of the LLR data LLRD based on the updated values of the variable nodes. If the decoding of the LLR data LLRD is successfully performed, the decoder 420 may output the decoded data Data_D. If the decoding of the LLR data LLRD fails (e.g., if all errors in the read data Data_R are not corrected), the decoder 420 may output the read error message ERR.

The decoder 420 may include a variable node processor (“VNP”) 421, a first switch network (“SWN1”) 422, a check node processor (“CNP”) 423, a second switch network (“SWN2”) 424, and a determination logic circuit 425. In LDPC decoding, nonzero elements of a parity check matrix indicate that corresponding pairs of variable and check nodes are connected. Decoding is performed through data exchanged via these connections between the variable nodes and the check nodes.

The variable node processor 421 may store the LLR data LLRD, including variable nodes A2, B2, C2, D2, E2, F2, and G2 of FIG. 13, and provide the LLR data LLRD as a variable node message VNM to the first switch network 422. The check node processor 423, connected to the variable node processor 421 via the first switch network 422, may process the values of the variable nodes A2, B2, C2, D2, E2, F2, and G2 for each of check nodes A1, B1, C1, and D1 of FIG. 13 by referencing the variable node message VNM and provide a resulting check node message CNM to the second switch network 424. The variable node processor 421, connected to the check node processor 423 via the second switch network 424, may update the values of the variable nodes A2, B2, C2, D2, E2, F2, and G2 by referencing the check node message CNM and perform decoding of the LLR data LLRD based on the updated values of the variable nodes A2, B2, C2, D2, E2, F2, and G2.

The determination logic circuit 425 may correct errors in the second read data RD2 based on the decoding results from the variable node processor 421 and provide the decoded data Data_D. If errors cannot be corrected, the determination logic circuit 425 may output the read error message ERR.

The ECC decoding operation of the ECC decoder 217b of FIG. 12 will hereinafter be described with reference to FIG. 13. FIG. 13 assumes that the ECC decoder 217b performs ECC decoding using an LDPC code.

An LDPC code is a code that provides error correction capabilities close to the channel capacity, and is widely used in communication systems, communication standards, and memory controllers due to its excellent error correction capabilities. As a linear block code, an LDPC code may be defined by a parity check matrix (PCM). Here, a code represents the relationship between information words and parity bits.

An LDPC code with a codeword length of n and an information word length of k may be represented by a (n−k)×n PCM. In general, an LDPC code with a greater codeword length exhibits better error correction capabilities.

Referring to FIG. 13, the Tanner graph includes the variable nodes A2, B2, C2, D2, E2, F2, and G2, the check nodes A1, B1, C1, and D1, and edges connecting the variable nodes A2, B2, C2, D2, E2, F2, and G2 and the check nodes A1, B1, C1, and D1. The variable nodes A2, B2, C2, D2, E2, F2, and G2 are associated with the bits of codewords, and the check nodes A1, B1, C1, and D1 are associated with parity check constraints. Also, “1” elements of a PCM correspond to the edges of the Tanner graph. The number of edges connected to each node is defined as the degree of the corresponding node. The LLR values of the LLR set selected by the LLR set selection circuit 220 may be applied to the variable nodes A2, B2, C2, D2, E2, F2, and G2.

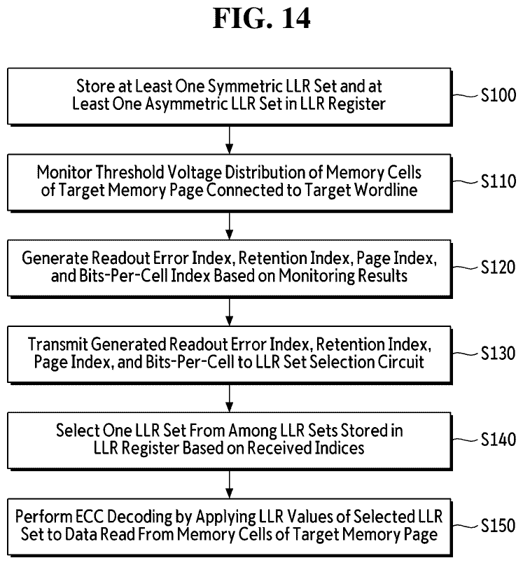

FIG. 14 is a flowchart illustrating an operating method of a storage device according to some embodiments.

Referring to FIGS. 12 and 14, at least one symmetric LLR set and at least one asymmetric LLR set may first be stored in the LLR set register 410 (S100). Thereafter, the LLR optimization circuit 219 may monitor the threshold voltage distributions of memory cells in a target memory page connected to a target wordline (S110). For example, the LLR optimization circuit 219 may select one wordline to be monitored, e.g., the target wordline, from among the wordlines WL(1) through WL(n) (of FIG. 4) included in the memory cell array 330.

Additionally, the LLR optimization circuit 219 may select one memory page to be monitored, e.g., the target memory page, from among a plurality of memory pages that constitute the target wordline. For example, if the memory cell array 330 includes 4-bit QLCs, the LLR optimization circuit 219 may select one page from among the MSB page, USB page, ESB page, and LSB page constituting the target wordline as the target memory page.

Thereafter, the LLR optimization circuit 219 may generate a read error index E_IDX, a retention index R_IDX, a page index P_IDX, and a bits-per-cell index B_IDX based on the results of monitoring the threshold voltage distributions of the memory cells in the target memory page (S120). For example, the LLR optimization circuit 219 may perform a hard-decision read operation with respect to a reference voltage level for the memory cells in the target memory page and count the number of cases in which memory cells storing data with the first logic level are erroneously read as data with the second logic level and the number of cases in which memory cells storing data with the second logic level are erroneously read as data with the first logic level. The LLR optimization circuit 219 may generate the read error index E_IDX, which includes information regarding the probability of data with the first logic level being erroneously read as data with the second logic level and the probability of data with the second logic level being erroneously read as data with the first logic level, based on the results of the counting.

Additionally, the LLR optimization circuit 219 may determine the degree of charge shift caused by data retention based on a cell counting operation for the memory cells in the target memory page. For example, during a read operation performed by applying a read voltage to the memory cells in higher states (e.g., the fifteenth program state P15 of FIG. 8) in the target memory page, if the number of off-cells is smaller than the number of on-cells, the LLR optimization circuit 219 may determine that charge loss caused by data retention has occurred. If the deviation between the numbers of off-cells and on-cells is significant, the LLR optimization circuit 219 may determine that the deviation (e.g., asymmetry) between the probability of data with the first logic level being erroneously read as data with the second logic level and the probability of data with the second logic level being erroneously read as data with the first logic level is greater.

In another embodiment, the LLR optimization circuit 219 may determine the degree of charge shift caused by data retention based on the threshold voltage distributions of the memory cells in the target memory page. For example, if the reference threshold voltage value VR (of FIG. 8) of the memory cells in the highest state (e.g., the fifteenth program state P15 of FIG. 8) is smaller than a desired and/or alternatively predetermined threshold voltage value, the LLR optimization circuit 219 may determine that charge loss caused by data retention has occurred. Additionally, if the deviation between the reference threshold voltage value VR and the desired and/or alternatively predetermined threshold voltage value is significant, the LLR optimization circuit 219 may determine that the deviation (e.g., asymmetry) between the probabilities of erroneous readout of data with the first and second logic levels is considerably large.

In this manner, the LLR optimization circuit 219 may generate the retention index R_IDX, which includes information regarding the degree of charge shift caused by data retention for the memory cells in the target memory page.

Thereafter, the LLR optimization circuit 219 may transmit the generated read error index E_IDX, retention index R_IDX, page index P_IDX, and bits-per-cell index B_IDX to the LLR set selection circuit 220 (S130).

Thereafter, the LLR set selection circuit 220 may select one of the LLR sets stored in the LLR set register 410 based on at least one of the received indices (S140). If the deviation between the probability of data with the first logic level being erroneously read as data with the second logic level and the probability of data with the second logic level being erroneously read as data with the first logic level is determined to be smaller than a desired and/or alternatively predetermined threshold based on the received indices, the LLR set selection circuit 220 may select a symmetric LLR set from among the LLR sets stored in the LLR set register 410.

Conversely, if the deviation between the probability of data with the first logic level being erroneously read as data with the second logic level and the probability of data with the second logic level being erroneously read as data with the first logic level is determined to be greater than the desired and/or alternatively predetermined threshold based on the received indices, the LLR set selection circuit 220 may select an asymmetric LLR set from among the LLR sets stored in the LLR set register 410.

At this time, the LLR set selection circuit 220 may determine the magnitude of the asymmetry between the probability of data with the first logic level being erroneously read as data with the second logic level and the probability of data with the second logic level being erroneously read as data with the first logic level based on the received indices. If this asymmetry is determined to be relatively significant, the LLR set selection circuit 220 may select an asymmetric LLR set from among the asymmetric LLR sets stored in the LLR set register 410 that includes LLR values with a relatively large asymmetry in their absolute values with respect to the reference read voltage.

Finally, the ECC decoder 217b may perform ECC decoding by applying the LLR values of the LLR set selected by the LLR set selection circuit 220 to the data read from the memory cells in the target memory page (S150).

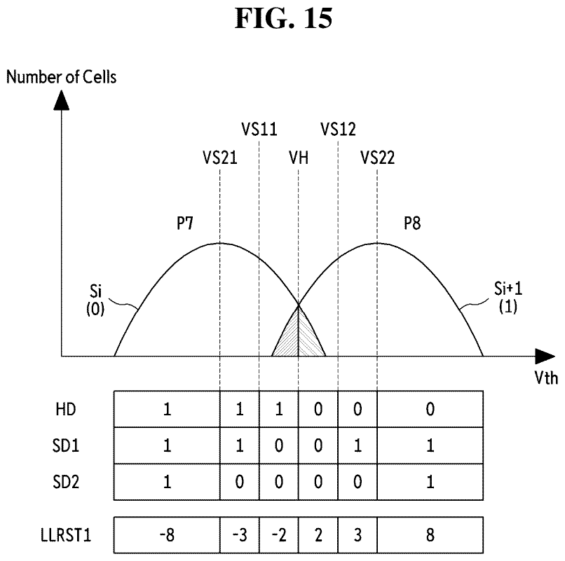

FIGS. 15 through 17 are diagrams illustrating how to perform ECC decoding by applying LLR values to data read from memory cells, according to some embodiments.

FIG. 15 is a diagram illustrating how the ECC decoder according to some embodiments performs ECC decoding by applying first LLR values from a first LLR set LLRST1, which is a symmetric LLR set, to data read from memory cells in the intermediate states of FIG. 9.

FIG. 16 is a diagram illustrating how the ECC decoder according to some embodiments performs ECC decoding by applying second LLR values from a second LLR set LLRST2, which is an asymmetric LLR set, to data read from memory cells in the higher states of FIG. 10.

FIG. 17 is a diagram illustrating how the ECC decoder according to some embodiments performs ECC decoding by applying third LLR values from a third LLR set LLRST3, which is an asymmetric LLR set, to data read from memory cells in the lower states of FIG. 11.

Referring to FIG. 15, the ECC decoder 217b may perform a hard-decision decoding operation HD using a reference read voltage VH on data read from memory cells in the intermediate states of FIG. 9, and may perform a first soft-decision decoding operation SD1 and a second soft-decision decoding operation SD2 on data read from the memory cells in the intermediate states using offset read voltages VS11, VS12, VS21, and VS22. In this case, the reliability of data read during the hard-decision decoding operation HD may be determined by the first LLR values of the first LLR set LLRST1 as −8, −3, −2, 2, 3, and 8. That is, the threshold voltage distributions of the memory cells in the intermediate states may be divided into six sections using five voltages, e.g., the reference read voltage VH and the offset read voltages VS11, VS12, VS21, and VS22, and an LLR value may be assigned to the memory cells in each of the six sections.

At this time, since the probability of readout errors occurring in memory cells in the seventh program state P7 is similar to that in memory cells in the eighth program state P8 (e.g., the deviation between the probability of data in the memory cells in the seventh program state P7 being erroneously read as “1” and the probability of data in the memory cells in the eighth program state P8 being erroneously read as “0” is smaller than a desired and/or alternatively predetermined threshold), the LLR optimization circuit 219 may select the first LLR set LLRST1, which includes first LLR values having symmetric absolute values with respect to the reference read voltage VH. The ECC decoder 217b may perform ECC decoding using the first LLR values of the first LLR set LLRST1.

Referring to FIG. 16, the ECC decoder 217b may perform a hard-decision decoding operation HD using a reference read voltage VH on data read from memory cells in the higher states of FIG. 10, and may perform a first soft-decision decoding operation SD1 and a second soft-decision decoding operation SD2 on data read from the memory cells in the higher states using offset read voltages VS11, VS12, VS21, and VS22. In this case, the reliability of data read during the hard-decision decoding operation HD may be determined by the second LLR values of the second LLR set LLRST2 as −8, −2, −1, 2, 3, and 8. That is, the threshold voltage distributions of the memory cells in the higher states may be divided into six sections using five voltages, e.g., the reference read voltage VH and the offset read voltages VS11, VS12, VS21, and VS22, and an LLR value may be assigned to the memory cells in each of the six sections.

At this time, the probability of memory cells in the fifteenth program state P15 being erroneously read as “0” may be greater than the probability of memory cells in the fourteenth program state P14 being erroneously read as “1.” The deviation between the probability of memory cells in the fifteenth program state P15 being erroneously read as “0” and the probability of memory cells in the fourteenth program state P14 being erroneously read as “1” may be greater than the desired and/or alternatively predetermined threshold. In this case, the LLR optimization circuit 219 may select the second LLR set LLRST2, which includes second LLR values having asymmetric absolute values with respect to the reference read voltage VH. The ECC decoder 217b may perform ECC decoding using the second LLR values of the second LLR set LLRST2.

As the threshold voltage values of memory cells approach the reference read voltage VH, the reliability of data read from the memory cells decreases, and thus, the absolute values of LLR values may decrease. Furthermore, since the probability of memory cells in the fifteenth program state P15 being erroneously read as “0” is greater than the probability of memory cells in the fourteenth program state P14 being erroneously read as “1,” the absolute values of LLR values of −1 and −2 applied to memory cells in the fifteenth program state P15 with readout errors may be smaller than the absolute values of LLR values of −2 and −3 applied to memory cells in the fourteenth program state P14 with readout errors. Consequently, a lower reliability may be applied to the memory cells in the fifteenth program state P15 with readout errors than to the memory cells in the fourteenth program state P14 with readout errors.

However, the memory cells in the fifteenth program state P15 with threshold voltage values significantly greater than the reference read voltage VH and memory cells in the fourteenth program state P14 with threshold voltage values significantly smaller than the reference read voltage VH are less likely to experience readout errors and may thus be assigned LLR values with large absolute values (e.g., with high reliability), such as 8 and −8, respectively. Additionally, the LLR values applied to the memory cells in the fifteenth program state P15 with threshold voltage values significantly greater than the reference read voltage VH and the LLR values applied to the memory cells in the fourteenth program state P14 with threshold voltage values significantly smaller than the reference read voltage VH may be symmetric (e.g., identical).

Referring to FIG. 17, the ECC decoder 217b may perform a hard-decision decoding operation HD using a reference read voltage VH on data read from memory cells in the lower states of FIG. 11, and may perform first, second, and third soft-decision decoding operations SD1, SD2, and SD3 on data read from the memory cells in the lower states using offset read voltages VS11, VS12, VS21, VS22, and VS32. In this case, the reliability of data read during the hard-decision decoding operation HD may be determined by the third LLR values of the third LLR set LLRST3 as −8, −3, −2, 1, 2, and 4. That is, the threshold voltage distributions of the memory cells in the lower states may be divided into seven sections using six voltages, e.g., the reference read voltage VH and the offset read voltages VS11, VS12, VS21, VS22, and VS32, and an LLR value may be assigned to the memory cells in each of the seven sections.

At this time, the probability of memory cells in the erase state E being erroneously read as “1” may be greater than the probability of memory cells in the first program state P1 being erroneously read as “0.” The deviation between the probability of memory cells in the erase state E being erroneously read as “1” and the probability of memory cells in the first program state P1 being erroneously read as “0” may be greater than the desired and/or alternatively predetermined threshold. In this case, the LLR optimization circuit 219 may select the third LLR set LLRST3, which includes third LLR values having asymmetric absolute values with respect to the reference read voltage VH. The ECC decoder 217b may perform ECC decoding using the third LLR values of the third LLR set LLRST3.

As the threshold voltage values of memory cells approach the reference read voltage VH, the reliability of data read from the memory cells decreases, and thus, the absolute values of LLR values may decrease. Furthermore, since the probability of memory cells in the erase state E being erroneously read as “1” is greater than the probability of memory cells in the first program state P1 being erroneously read as “0,” the absolute values of LLR values of 1 and 2 applied to memory cells in the erase state E with readout errors may be smaller than the absolute values of LLR values of −2 and −3 applied to memory cells in the first program state P1 with readout errors.

However, memory cells in the first program state P1 with threshold voltage values significantly greater than the reference read voltage VH and memory cells in the erase state E with threshold voltage values significantly smaller than the reference read voltage VH are less likely to experience readout errors and may thus be assigned LLR values with large absolute values (e.g., with high reliability), such as 8 and −8, respectively. Additionally, the LLR values applied to memory cells in the first program state P1 with threshold voltage values significantly greater than VH and the LLR values applied to the memory cells in the erase state E with threshold voltage values significantly smaller than the reference read voltage VH may be symmetric (e.g., identical).

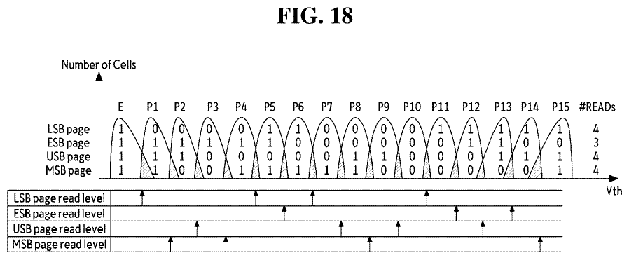

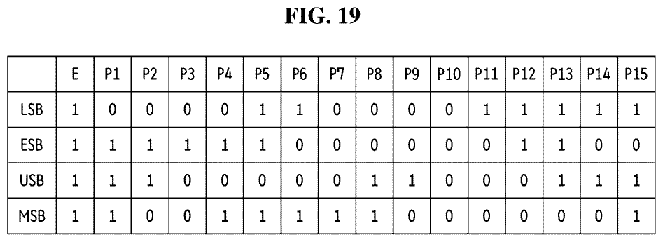

FIGS. 18 and 19 are diagrams illustrating bit mapping for programming memory cells and read levels for respective memory pages when the memory cells in the memory cell array of FIG. 4 are 4-bit QLCs.

FIGS. 18 and 19 assume that the memory cells in the memory cell array of FIG. 4 are QLCs for convenience of explanation, but the present disclosure is not limited thereto.

Referring to FIGS. 18 and 19, in the case of QLCs, each memory cell may store LSBs, ESBs, USBs, and MSBs. Referring also to FIG. 4, LSBs stored in a first row of memory cells connected to the target wordline may form a lowest bit page, and MSBs stored in the same memory cells may form a highest bit page. Additionally, USBs stored in the same memory cells may form a second highest bit page, and ESBs stored in the same memory cells may form a bit page between the USBs and the LSBs.

As shown in FIG. 18, the MSB page, USB page, ESB page, and LSB page of the target wordline may each have multiple read levels, and the read levels for each memory page may differ. Additionally, the number of reads may vary for each memory page. The bit mapping shown in FIGS. 18 and 19 is merely examples, and bit mapping for programming memory cells may vary from embodiment to embodiment.

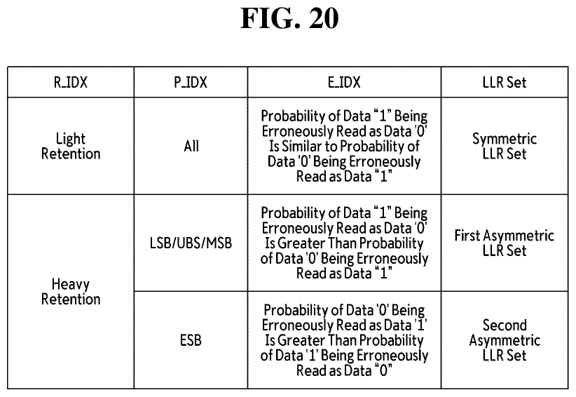

FIG. 20 is a diagram illustrating how the LLR set selection circuit selects different LLR sets based on indices received from the LLR optimization circuit for a memory device including the QLCs shown in FIG. 18.

Referring to FIG. 20, the LLR optimization circuit 219 (of FIG. 12) may determine the severity of charge shift caused by data retention by monitoring the threshold voltage distributions of the memory cells connected to the target wordline, and may generate a retention index R_IDX based on the results of the determination. If the charge shift caused by data retention is determined to be light (“Light Retention”), the LLR set selection circuit 220 may select a symmetric LLR set for all memory pages constituting the target wordline. In this case, a read error index E_IDX generated by the LLR optimization circuit 219 may include information indicating that the probability of data “1” being erroneously read as data “0” is similar to the probability of data “0” being erroneously read as data “1.” That is, the read error index E_IDX may include information indicating that the deviation between the probability of data with the first logic level being erroneously read as data with the second logic level and the probability of data with the second logic level being erroneously read as data with the first logic level is smaller than a desired and/or alternatively predetermined threshold.

Conversely, if the LLR optimization circuit 219 determines that the charge shift caused by retention is severe (“Heavy Retention”), e.g., the deviation between the probability of data with the first logic level being erroneously read as data with the second logic level and the probability of data with the second logic level being erroneously read as data with the first logic level exceeds the desired and/or alternatively predetermined threshold, the LLR optimization circuit 219 may generate a read error index E_IDX for each memory page.

The LLR set selection circuit 220 may select a first asymmetric LLR set for the memory cells connected to the LSB page, USB page, and MSB page if, based on the read error index E_IDX generated for each memory page, the probability of data “1” being erroneously read as data “0” is determined to be greater than the probability of data “0” being erroneously read as data “1.” Additionally, the LLR set selection circuit 220 may select a second asymmetric LLR set for the memory cells connected to the ESB page if the probability of data “0” being erroneously read as data “1” is determined to be greater than the probability of data “1” being erroneously read as data “0.”

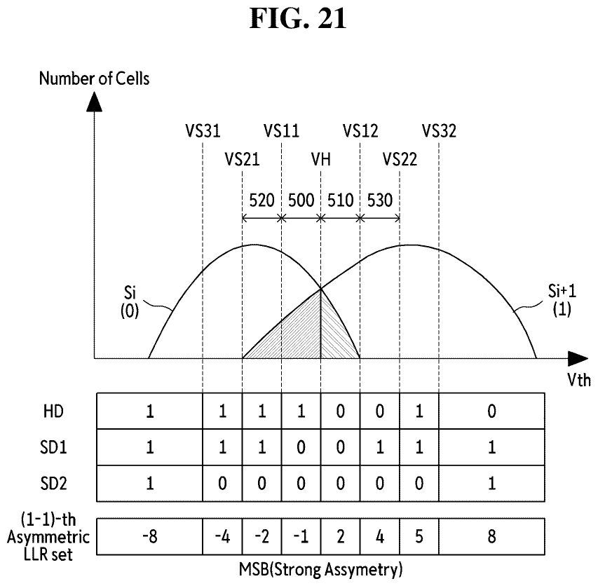

In other words, the LLR set selection circuit 220 may compare the probabilities of data “0” being erroneously read as data “1” and data “1” being erroneously read as data “0” for each of the memory pages constituting the target wordline and select different asymmetric LLR sets based on the results of the comparison. The first and second asymmetric LLR sets of FIG. 20 will be described later with reference to FIGS. 21 through 23.

Meanwhile, FIG. 20 assumes that the probability of data “0” being erroneously read as data “1” is greater than the probability of data “1” being erroneously read as data “0” for the memory cells connected to the ESB page, and that the probability of data “1” being erroneously read as data “0” is greater than the probability of data “0” being erroneously read as data “1” for the memory cells connected to the LSB page, USB page, and MSB page, but the present disclosure is not limited thereto. That is, which type of readout error is more probable for each of the memory pages constituting the target wordline may vary from embodiment to embodiment.

FIGS. 21 through 23 are diagrams illustrating how the ECC decoder performs ECC decoding by applying LLR values to data read from memory cells in the target memory page connected to the target wordline.

FIG. 21 shows the threshold voltage distributions of memory cells in all program states of the MSB page (e.g., the erase state E and the first through fifteenth program states P1 through P15 of FIG. 18) when the target memory page is the MSB page. In this case, the threshold voltage distributions of memory cells in all the program states of the MSB page may include a first state Si corresponding to data “0” and a second state Si+1 corresponding to data “1.”

The ECC decoder 217b may perform a hard-decision decoding operation HD using a reference read voltage VH on data read from the memory cells in all the program states of the MSB page, and may perform first, second, and third soft-decision decoding operations SD1, SD2, and SD3 on the data read from the memory cells using offset read voltages VS11, VS12, VS21, VS22, V31, and V32. In this case, the reliability of the data read during the hard-decision decoding operation HD may be determined by (1-1)-th LLR values from a (1-1)-th asymmetric LLR set as −8, −4, −2, −1, 2, 4, 5, and 8.

In other words, the threshold voltage distributions of the memory cells in all the program states of the MSB page may be divided into eight sections using seven voltages, e.g., the reference read voltage VH and the offset read voltages VS11, VS12, VS21, VS22, V31, and V32, and an LLR value may be assigned to the memory cells in each of the eight sections.

At this time, the probability of memory cells storing data “1” being erroneously read as data “0” may be greater than the probability of memory cells storing data “0” being erroneously read as data “1” among the memory cells in all the program states of the MSB page. Accordingly, the LLR set selection circuit 220 may select the (1-1)-th asymmetric LLR set, which includes (1-1)-th LLR values having asymmetric absolute values with respect to the reference read voltage VH. The ECC decoder 217b may perform ECC decoding using the (1-1)-th LLR values of the (1-1)-th asymmetric LLR set.

As the threshold voltage values of memory cells approach the reference read voltage VH, the reliability of data read from the memory cells decreases, and thus, the absolute values of LLR values may decrease. Furthermore, since the probability of memory cells storing data “1” being erroneously read as data “0” is greater than the probability of memory cells storing data “0” being erroneously read as data “1,” the absolute values of LLR values applied to memory cells in the second state Si+1 with readout errors may be smaller than the absolute values of LLR values applied to memory cells in the first state Si with readout errors.

For example, during the first soft-decision decoding operation SD1, the absolute value of an LLR value of −1, which is applied to data read from memory cells in a section 500 between the reference read voltage VH and the (1-1)-th soft-decision read voltage VS11, e.g., 1, may be smaller than the absolute value of an LLR value of 2, which is applied to data read from memory cells in a section 510 between the reference read voltage VH and the (1-2)-th soft-decision read voltage VS12, e.g., 2.

Similarly, during the second soft-decision decoding operation SD2, the absolute value of an LLR value of −2, which is applied to data read from memory cells in a section 520 between the (1-1)-th soft-decision read voltage VS11 and the (2-1)-th soft-decision read voltage VS21, e.g., 2, may be smaller than the absolute value of an LLR value of 4, which is applied to data read from memory cells in a section 530 between the (1-2)-th soft-decision read voltage VS12 and the (2-2)-th soft-decision read voltage VS22, e.g., 4.

However, memory cells in the second state Si+1 with threshold voltage values significantly greater than the reference read voltage VH and memory cells in the first state Si with threshold voltage values significantly smaller than the reference read voltage VH are less likely to experience readout errors and may thus be assigned LLR values with large absolute values (e.g., high reliability), such as 8 and −8.

Additionally, the LLR values applied to the memory cells in the second state Si+1 with threshold voltage values significantly greater than the reference read voltage VH and the LLR values applied to the memory cells in the first state Si with threshold voltage values significantly smaller than the reference read voltage VH may be symmetric (e.g., identical).

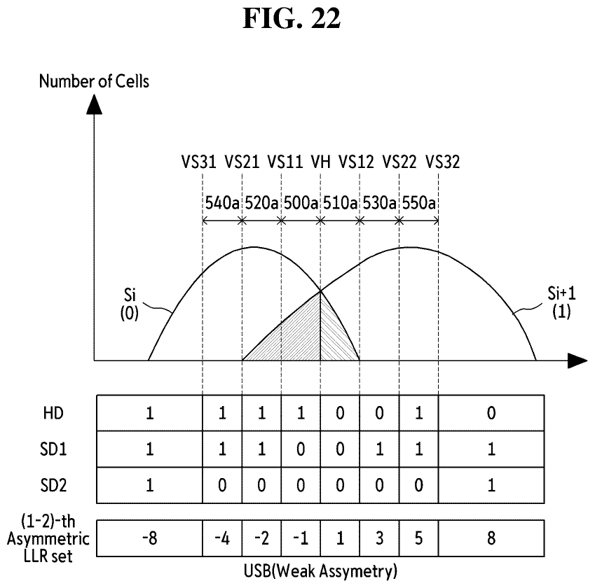

FIG. 22 shows the threshold voltage distributions of memory cells in all the program states of the USB page (e.g., the erase state E and the first through fifteenth program states P1 through P15 of FIG. 18) when the target memory page is the USB page. In this case, the threshold voltage distributions of the memory cells in all the program states of the USB page may include a first state Si corresponding to data “0” and a second state Si+1 corresponding to data “1.”

Meanwhile, the LLR set selection circuit 220 may obtain information regarding the severity of charge shift caused by data retention for each memory page constituting the target wordline based on the retention index R_IDX received from the LLR optimization circuit 219. For example, the LLR set selection circuit 220 may determine, based on the retention index R_IDX, that the degree of charge shift caused by data retention for the threshold voltage distributions of memory cells in the MSB page is greater than the degree of charge shift caused by data retention for the threshold voltage distributions of memory cells in the USB page.

In other words, the MSB page may be in a strong asymmetry state, where the deviation between the probability of memory cells storing data “1” being erroneously read as data “0” and the probability of memory cells storing data “0” being erroneously read as data “1” is relatively large. Conversely, the USB page may be in a weak asymmetry state, where the deviation between these probabilities is relatively small.

Thus, the LLR set selection circuit 220 may select different asymmetric LLR sets from among the asymmetric LLR sets stored in the LLR set register 410 for each memory page based on the degree of asymmetry of the target memory page. For example, the LLR set selection circuit 220 may select a (1-2)-th asymmetric LLR set for data read from memory cells in the USB page, which is different from the (1-1)-th asymmetric LLR set selected for the MSB page.

The ECC decoder 217b may perform a hard-decision decoding operation HD using a reference read voltage VH on data read from the memory cells in all program states of the USB page, and may perform first, second, and third soft-decision decoding operations SD1, SD2, and SD3 on the data read from the memory cells using offset read voltages VS11, VS12, VS21, VS22, V31, and V32. In this case, the reliability of the data read during the hard-decision decoding operation HD may be determined by (1-2)-th LLR values from the (1-2)-th asymmetric LLR set as −8, −4, −2, −1, 1, 3, 5, and 8.

In other words, the threshold voltage distributions of the memory cells in all the program states of the USB page may be divided into eight sections using seven voltages, e.g., the reference read voltage VH and the offset read voltages VS11, VS12, VS21, VS22, V31, and V32, and an LLR value may be assigned to the memory cells in each of the eight sections.

At this time, the probability of memory cells storing data “1” being erroneously read as data “0” may be greater than the probability of memory cells storing data “0” being erroneously read as data “1” among the memory cells in all the program states of the USB page. Accordingly, the LLR set selection circuit 220 may select the (1-2)-th asymmetric LLR set, which includes (1-2)-th LLR values having asymmetric absolute values with respect to the reference read voltage VH. The ECC decoder 217b may perform ECC decoding using the (1-2)-th LLR values of the (1-2)-th asymmetric LLR set.

As the threshold voltage values of memory cells approach the reference read voltage VH, the reliability of data read from the memory cells decreases, and thus, the absolute values of LLR values may decrease. Furthermore, since the probability of memory cells storing data “1” being erroneously read as data “0” is greater than the probability of memory cells storing data “0” being erroneously read as data “1,” the absolute values of LLR values applied to memory cells in the second state Si+1 with readout errors may be smaller than the absolute values of LLR values applied to memory cells in the first state Si with readout errors.

For example, the absolute value of an LLR value of −2, which is applied to data read from memory cells in a section 520a between the (1-1)-th soft-decision read voltage VS11 and the (2-1)-th soft-decision read voltage VS21, e.g., 2, may be smaller than the absolute value of an LLR value of 3, which is applied to data read from memory cells in a section 530a between the (1-2)-th soft-decision read voltage VS12 and the (2-2)-th soft-decision read voltage VS22, e.g., 3.

Similarly, the absolute value of an LLR value of −4, which is applied to data read from memory cells in a section 540a between the (2-1)-th soft-decision read voltage VS21 and the (3-1)-th soft-decision read voltage VS31, e.g., 4, may be smaller than the absolute value of an LLR value of 5, which is applied to data read from memory cells in a section 550a between the (2-2)-th soft-decision read voltage VS22 and the (3-2)-th soft-decision read voltage VS32, e.g., 5.

However, memory cells in the second state Si+1 with threshold voltage values significantly greater than the reference read voltage VH and memory cells in the first state Si with threshold voltage values significantly smaller than the reference read voltage VH are less likely to experience readout errors and may thus be assigned LLR values with large absolute values (e.g., high reliability), such as 8 and −8. Additionally, the LLR values applied to the memory cells in the second state Si+1 with threshold voltage values significantly greater than the reference read voltage VH and the LLR values applied to the memory cells in the first state Si with threshold voltage values significantly smaller than the reference read voltage VH may be symmetric (e.g., identical).

Referring to both FIGS. 21 and 22, a deviation of 1 between the absolute value of the LLR value of −1 for the section 500 between the reference read voltage VH and the (1-1)-th soft-decision read voltage VS11 and the absolute value of the LLR value of 2 for the section 510 between the reference read voltage VH and the (1-2)-th soft-decision read voltage VS12 for the strongly asymmetric MSB page of FIG. 21 may be greater than a deviation of 0 between the absolute value of the LLR value of −1 and the absolute value of the LLR value of 1 for the weakly asymmetric USB page of FIG. 22.

Similarly, a deviation of 2 between the absolute value of the LLR value of −2 for the section 520 between the (1-1)-th soft-decision read voltage VS11 and the (2-1)-th soft-decision read voltage VS21 and the absolute value of the LLR value of 4 for the section 530 between the (1-2)-th soft-decision read voltage VS12 and the (2-2)-th soft-decision read voltage VS22 for the strongly asymmetric MSB page of FIG. 21 may be greater than a deviation of 1 between the absolute value of the LLR value of −2 and the absolute value of the LLR value of 3 for the section 530a between the (1-2)-th soft-decision read voltage VS12 and the (2-2)-th soft-decision read voltage VS22 for the weakly asymmetric USB page of FIG. 22.

In this manner, the LLR set selection circuit 220 may select different asymmetric LLR sets for each memory page from among the asymmetric LLR sets stored in the LLR set register 410 based on the degree of asymmetry included in the retention index R_IDX received from the LLR optimization circuit 219.

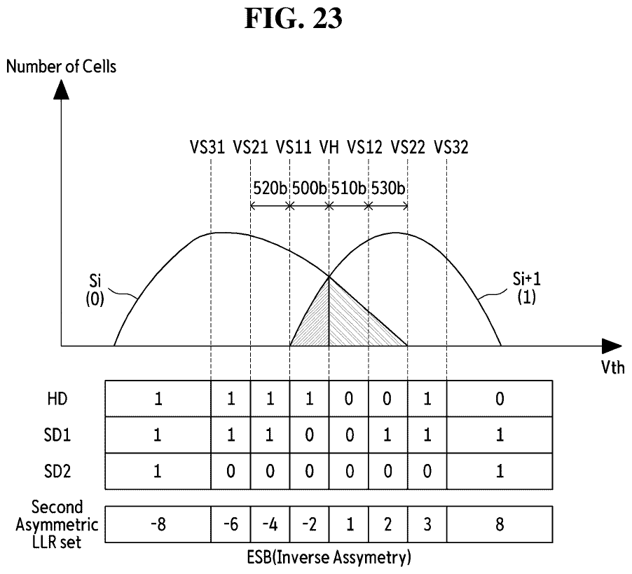

FIG. 23 shows the threshold voltage distributions of memory cells in all program states of the ESB page (e.g., the erase state E and the first through fifteenth program states P1 through P15 of FIG. 18) when the target memory page is the ESB page. At this time, the threshold voltage distributions of the memory cells in all the program states of the ESB page may include a first state Si corresponding to data “0” and a second state Si+1 corresponding to data “1.”

The ECC decoder 217b may perform a hard-decision decoding operation HD using a reference read voltage VH on data read from memory cells in all program states of the ESB page. Additionally, the ECC decoder 217b may perform first, second, and third soft-decision decoding operations SD1, SD2, and SD3 on the data read from the memory cells using offset read voltages VS11, VS12, VS21, VS22, V31, and V32. In this case, the reliability of the data read during the hard-decision decoding operation HD may be determined by the LLR values from the second asymmetric LLR set as −8, −6, −4, −2, 1, 2, 3, and 8.

In other words, the threshold voltage distributions of the memory cells in all the program states of the ESB page may be divided into eight sections using seven voltages, e.g., the reference read voltage VH and the offset read voltages VS11, VS12, VS21, VS22, V31, and V32, and an LLR value may be assigned to the memory cells in each of the eight sections.

Referring to FIG. 23, unlike the MSB and USB pages of FIGS. 21 and 22, the ESB page may exhibit an inverse asymmetry state, where the probability of memory cells storing data “0” being erroneously read as data “1” is greater than the probability of memory cells storing data “1” being erroneously read as data “0.”

The LLR set selection circuit 220 may select the second asymmetric LLR set, which includes LLR values having asymmetric absolute values with respect to the reference read voltage VH. The ECC decoder 217b may perform ECC decoding using the second asymmetric LLR values of the second asymmetric LLR set.

As the threshold voltage values of memory cells approach the reference read voltage VH, the reliability of data read from the memory cells decreases, and thus, the absolute values of LLR values may decrease. Furthermore, since the probability of memory cells storing data “0” being erroneously read as data “1” is greater than the probability of memory cells storing data “1” being erroneously read as data “0,” the absolute values of LLR values applied to memory cells in the second state Si+1 with readout errors may be smaller than the absolute values of LLR values applied to memory cells in the first state Si with readout errors.

For example, the absolute value of an LLR value of 1, which is applied to data read from memory cells in a section 510b between the reference read voltage VH and the (1-2)-th soft-decision read voltage VS12, e.g., 1, may be smaller than the absolute value of an LLR value of −2, which is applied to data read from memory cells in a section 500b between the reference read voltage VH and the (1-1)-th soft-decision read voltage VS11, e.g., 2.

Similarly, the absolute value of an LLR value of 2, which is applied to data read from memory cells in a section 530b between the (1-2)-th soft-decision read voltage VS12 and the (2-2)-th soft-decision read voltage VS22, e.g., 2, may be smaller than the absolute value of an LLR value of −4, which is applied to data read from memory cells in a section 520b between the (1-1)-th soft-decision read voltage VS11 and the (2-1)-th soft-decision read voltage VS21, e.g., 4.

However, memory cells in the second state Si+1 with threshold voltage values significantly greater than the reference read voltage VH and memory cells in the first state Si with threshold voltage values significantly smaller than the reference read voltage VH are less likely to experience readout errors and may thus be assigned LLR values with large absolute values (e.g., high reliability), such as 8 and −8. Additionally, the LLR values applied to the memory cells in the second state Si+1 with threshold voltage values significantly greater than the reference read voltage VH and the LLR values applied to the memory cells in the first state Si with threshold voltage values significantly smaller than the reference read voltage VH may be symmetric (e.g., identical).

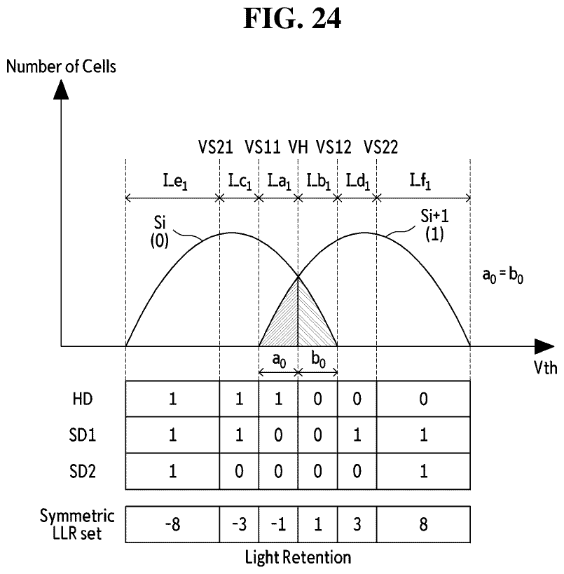

FIGS. 24 through 27 are diagrams illustrating how the ECC decoder according to some embodiments performs ECC decoding by applying LLR values to data read from memory cells of each memory page.

The embodiment of FIGS. 24 through 27 will hereinafter be described, omitting redundant descriptions and focusing mainly on the differences from the embodiment of FIGS. 21 through 23.

Referring first to FIG. 24, the LLR optimization circuit 219 of FIG. 12 may determine, based on the results of monitoring the threshold voltage distributions of memory cells in a memory page connected to the target wordline, that the severity of charge shift caused by retention is light (“Light Retention”), and may then transmit a retention index R_IDX, including corresponding information, to the LLR set selection circuit 220. Based on the retention index R_IDX received from the LLR optimization circuit 219, the LLR set selection circuit 220 may select a symmetric LLR set from among the LLR sets stored in the LLR set register 410 of FIG. 12. Here, the symmetric LLR set may include LLR sections that are symmetric in width with respect to a reference read voltage VH and LLR values respectively corresponding to the LLR sections.

For example, referring to FIG. 24, the LLR set selection circuit 220 may apply the symmetric LLR set to a memory page in the light retention state. In this case, the symmetric LLR set may include LLR values of −8, −3, −1, 1, 3, and 8.

The ECC decoder 217b may perform a hard-decision decoding operation HD using the reference read voltage VH on data read from memory cells connected to the target wordline, and may perform first and second soft-decision decoding operations SD1 and SD2 on the data using offset read voltages VS11, VS12, VS21, and VS22. In this case, the reliability of the data read during the hard-decision decoding operation HD may be determined by the LLR values of the symmetric LLR set as −8, −3, −1, 1, 3, and 8.

In other words, the threshold voltage distributions of memory cells in the memory page connected to the target wordline may be divided into six sections I_a₁, I_b₁, I_c₁, I_d₁, I_e₁, and I_f₁ using five voltages, e.g., the reference read voltage VH and offset read voltages VS11, VS12, VS21, and VS22, and an LLR value may be assigned to the memory cells in each of the six sections.

Referring to FIG. 24, the symmetric LLR set may include a plurality of LLR sections I_a₁, I_b₁, I_c₁, I_d₁, I_e₁, and I_f₁. The LLR section I_a₁ may correspond to the section between the reference read voltage VH and the (1-1)-th soft-decision read voltage VS11, and the LLR section I_b₁ may correspond to the section between the reference read voltage VH and the (1-2)-th soft-decision read voltage VS12. The LLR sections I_a₁ and I_b₁ may be symmetric with respect to the reference read voltage VH. Similarly, the LLR section I_c₁ may correspond to the section between the (1-1)-th soft-decision read voltage VS11 and the (2-1)-th soft-decision read voltage VS21, and the LLR section I_d₁ may correspond to the section between the (1-2)-th soft-decision read voltage VS12 and the (2-2)-th soft-decision read voltage VS22. The LLR section I_e₁ may correspond to the section where the threshold voltage values of memory cells are smaller than the (2-1)-th soft-decision read voltage VS21, and the LLR section I_f₁ may correspond to the section where the threshold voltage values of memory cells are greater than the (2-2)-th soft-decision read voltage VS22.

For memory cells in a memory page in the light retention state, the deviation between the probability of memory cells storing data “1” being erroneously read as data “0” and the probability of memory cells storing data “0” being erroneously read as data “1” may be smaller than a desired and/or alternatively predetermined threshold. Accordingly, the LLR values applied to memory cells storing data “1” but being erroneously read as storing data “0” and the LLR values applied to memory cells storing data “0” but being erroneously read as storing data “1” need to have the same (or similar) reliability.

At this time, the symmetric LLR set selected by the LLR set selection circuit 220 may include the LLR values of −8, −3, −1, 1, 3, and 8, which have symmetric absolute values with respect to the reference read voltage VH. The widths of the LLR sections corresponding to these LLR values may also be identical.

For example, a width a₀ of the LLR section I_a₁ may be equal to a width b₀ of the LLR section I_b₁ (e.g., a₀=b₀). Consequently, LLR values with the same reliability (e.g., LLR values with the same absolute value of 1) may be applied to both the memory cells in the LLR section I_a₁ and the memory cells in the LLR section I_b₁, and the number of memory cells with a reliability of “1” applied thereto, among the memory cells storing data “1” but being erroneously read as storing data “0,” and the number of memory cells with the reliability of “1” applied thereto, among the memory cells storing data “0” but being erroneously read as storing data “1,” may be identical.

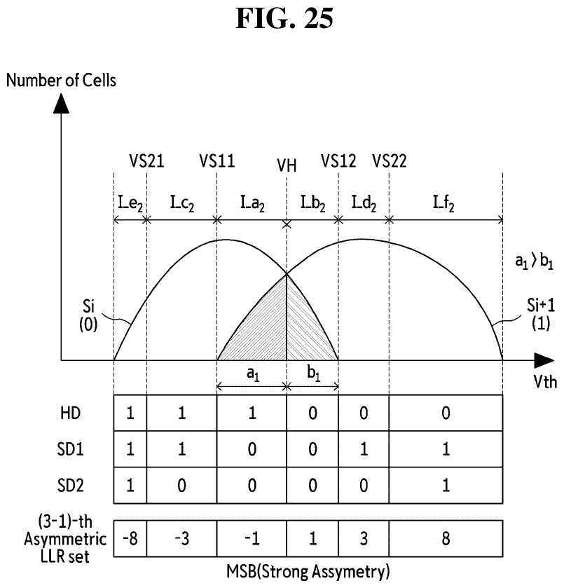

Referring to FIGS. 25 through 27, the LLR set selection circuit 220 of FIG. 12 may apply a (3-1)-th asymmetric LLR set, a (3-2)-th asymmetric LLR set, and a (3-3)-th asymmetric LLR set to an MSB page, a USB page, and an ESB page, respectively. The (3-1)-th asymmetric LLR set, (3-2)-th asymmetric LLR set, and (3-3)-th asymmetric LLR set may include (3-1)-th LLR values, (3-2)-th LLR values, and (3-3)-th LLR values, respectively.

The ECC decoder 217b may perform a hard-decision decoding operation HD using a reference read voltage VH on data read from memory cells in all program states of the MSB page, and may perform first and second soft-decision decoding operations SD1 and SD2 on the data read from the memory cells using offset read voltages VS11, VS12, VS21, and VS22. In this case, the reliability of the data read during the hard-decision decoding operation HD may be determined by the (3-1)-th LLR values of the (3-1)-th asymmetric LLR set as −8, −3, −1, 1, 3, and 8.

In other words, the threshold voltage distributions of memory cells in all the program states of the MSB page may be divided into six sections I_a₂, I_b₂, I_c₂, I_d₂, I_e₂, and I_f₂ using five voltages, e.g., the reference read voltage VH and the offset read voltages VS11, VS12, VS21, and VS22, and an LLR value may then be assigned to the memory cells in each of the six sections.

The ECC decoder 217b may perform a hard-decision decoding operation HD using the reference read voltage VH on data read from memory cells in all program states of the USB page. Additionally, the ECC decoder 217b may perform first and second soft-decision decoding operations SD1 and SD2 on the data read from the memory cells using offset read voltages VS11, VS12, VS21, and VS22. In this case, the reliability of the data read during the hard-decision decoding operation HD may be determined by the (3-2)-th LLR values of the (3-2)-th asymmetric LLR set as −8, −3, −1, 1, 3, and 8.

In other words, the threshold voltage distributions of memory cells in all the program states of the USB page may be divided into six sections I_a₃, I_b₃, I_c₃, I_d₃, I_e₃, and I_f₃ using five voltages, e.g., the reference read voltage VH and the offset read voltages VS11, VS12, VS21, and VS22, and an LLR value may then be assigned to the memory cells in each of the six sections.

The ECC decoder 217b may perform a hard-decision decoding operation HD using the reference read voltage VH on data read from memory cells in all program states of the ESB page, and may perform first and second soft-decision decoding operations SD1 and SD2 on the data read from the memory cells using offset read voltages VS11, VS12, VS21, and VS22. In this case, the reliability of the data read during the hard-decision decoding operation HD may be determined by the (3-3)-th LLR values of the (3-3)-th asymmetric LLR set as −8, −3, −1, 1, 3, and 8.

In other words, the threshold voltage distributions of memory cells in all the program states of the ESB page may be divided into six sections I_a₄, I_b₄, I_c₄, I_d₄, I_e₄, and I_f₄ using five voltages, e.g., the reference read voltage VH and the offset read voltages VS11, VS12, VS21, and VS22, and an LLR value may then be assigned to the memory cells in each of the six sections.

The (3-1)-th LLR values, the (3-2)-th LLR values, and the (3-3)-th LLR values assigned to the MSB page, the USB page, and the ESB page, respectively, in an asymmetry state may be identical to the LLR values of the symmetric LLR set of FIG. 24, e.g., −8, −3, −1, 1, 3, and 8. Additionally, the (3-1)-th LLR values, the (3-2)-th LLR values, and the (3-3)-th LLR values, respectively assigned to the MSB page in a strong asymmetry state, the USB page in a weak asymmetry state, and the ESB page in a reverse asymmetry state, may all be identical as −8, −3, −1, 1, 3, and 8. However, the widths of the LLR sections to which the LLR values are applied may differ from memory page to memory page.

For example, referring to FIG. 25, the (3-1)-th asymmetric LLR set may include a plurality of LLR sections I_a₂, I_b₂, I_c₂, I_d₂, I_e₂, and I_f₂. The LLR section I_a₂ may correspond to the section between the reference read voltage VH and the (1-1)-th soft-decision read voltage VS11, and the LLR section I_b₂ may correspond to the section between the reference read voltage VH and the (1-2)-th soft-decision read voltage VS12. The LLR sections I_a₂ and I_b₂ may be symmetric with respect to the reference read voltage VH. Similarly, the LLR section I_c₂ may correspond to the section between the (1-1)-th soft-decision read voltage VS11 and the (2-1)-th soft-decision read voltage VS21, and the LLR section I_d₂ may correspond to the section between the (1-2)-th soft-decision read voltage VS12 and the (2-2)-th soft-decision read voltage VS22. The LLR section I_e₂ may correspond to the section where the threshold voltage values of memory cells are smaller than the (2-1)-th soft-decision read voltage VS21, and the LLR section I_f₂ may correspond to the section where the threshold voltage values of memory cells are greater than the (2-2)-th soft-decision read voltage VS22.

For the MSB page, since the probability of memory cells storing data “1” being erroneously read as data “0” is greater than the probability of memory cells storing data “0” being erroneously read as data “1,” the LLR values assigned to memory cells storing data “1” but being erroneously read as storing data “0” need to have a lower reliability than the LLR values assigned to memory cells storing data “0” but being erroneously read as storing data “1.”

The (3-1)-th asymmetric LLR set selected by the LLR set selection circuit 220 may include (3-1)-th LLR values of −8, −3, −1, 1, 3, and 8, which have symmetric absolute values with respect to the reference read voltage VH. However, the widths of the LLR sections corresponding to these LLR values may differ.

For example, a width a₁ of the LLR section I_a₂ may be greater than a width b₁ of the LLR section I_b₂ (e.g., a₁>b₁). Consequently, LLR values with the same reliability (e.g., LLR values with the same absolute value of 1) may be applied to both the memory cells included in the LLR section I_a₂ and the memory cells included in the LLR section I_b₂, but the number of memory cells with a reliability of “1” applied thereto, among the memory cells storing data “1” but being erroneously read as storing data “0,” may be greater than the number of memory cells with the reliability of “1” applied thereto, among the memory cells storing data “0” but being erroneously read as storing data “1.”

Accordingly, for the MSB page, ECC decoding may be performed by applying LLR values with the same reliability to both memory cells storing data “1” but being erroneously read as storing data “0” and memory cells storing data “0” but being erroneously read as storing data “1.” However, LLR values with a lowest reliability (e.g., a smallest absolute value) may be applied more frequently to memory cells with a greater number of readout errors (e.g., memory cells storing data “1” but being erroneously read as storing data “0”) than to memory cells with a smaller number of readout errors (e.g., memory cells storing data “0” but being erroneously read as storing data “1”), thereby enhancing the error correction capability of the ECC decoder 217b.

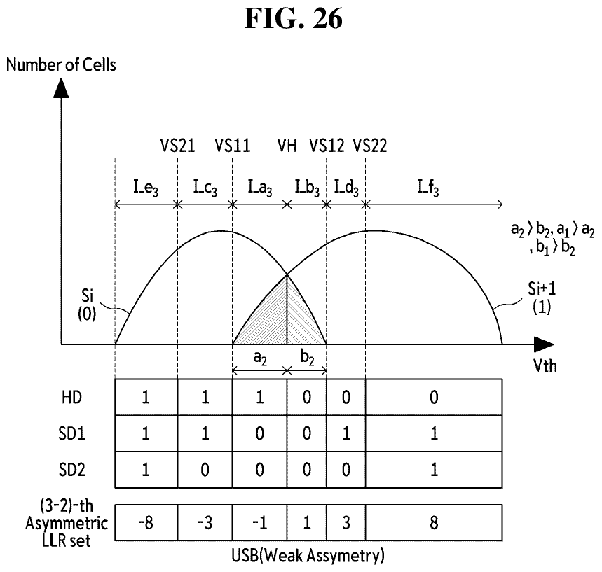

Referring to FIG. 26, the (3-2)-th asymmetric LLR set may include a plurality of LLR sections I_a₃, I_b₃, I_c₃, I_d₃, I_e₃, and I_f₃. The LLR section I_a₃ may correspond to the section between the reference read voltage VH and the (1-1)-th soft-decision read voltage VS11, and the LLR section I_b₃ may correspond to the section between the reference read voltage VH and the (1-2)-th soft-decision read voltage VS12. Similarly, the LLR section I_c₃ may correspond to the section between the (1-1)-th soft-decision read voltage VS11 and the (2-1)-th soft-decision read voltage VS21, and the LLR section I_d₃ may correspond to the section between the (1-2)-th soft-decision read voltage VS12 and the (2-2)-th soft-decision read voltage VS22. The LLR section I_e₃ may correspond to the section where the threshold voltage values of memory cells are smaller than the (2-1)-th soft-decision read voltage VS21, and the LLR section I_f₃ may correspond to the section where the threshold voltage values of memory cells are greater than the (2-2)-th soft-decision read voltage VS22.

For the USB page, since the probability of memory cells storing data “1” being erroneously read as storing data “0” is greater than the probability of memory cells storing data “0” being erroneously read as storing data “1,” LLR values with a lower reliability need to be applied to memory cells storing data “1” but being erroneously read as storing data “0” than to memory cells storing data “0” but being erroneously read as storing data “1.”

In this case, the (3-2)-th asymmetric LLR set selected by the LLR set selection circuit 220 may include (3-2)-th LLR values of −8, −3, −1, 1, 3, and 8, which have symmetric absolute values with respect to the reference read voltage VH. However, the widths of the LLR sections corresponding to these LLR values may differ.

For example, a width a₂ of the LLR section I_a₃ may be greater than a width b₂ of the LLR section I_b₃ (e.g., a₂>b₂). Accordingly, LLR values with the same reliability (e.g., LLR values with the same absolute value of 1) may be applied to both the memory cells included in the LLR section I_a₃ and the memory cells included in the LLR section I_b₃. However, the number of memory cells with a reliability of “1” applied thereto, among the memory cells storing data “1” but being erroneously read as storing data “0,” may be greater than the number of memory cells with the reliability of “1” applied thereto, among the memory cells storing data “0” but being erroneously read as storing data “1.”

Therefore, for the USB page, ECC decoding may be performed by applying LLR values with the same reliability to both memory cells storing data “1” but being erroneously read as storing data “0” and memory cells storing data “0” but being erroneously read as storing data “1.” However, LLR values with a lowest reliability (e.g., a smallest absolute value) may be applied more frequently to memory cells with a greater number of readout errors (e.g., memory cells storing data “1” but being erroneously read as storing data “0”) than to memory cells with a smaller number of readout errors (e.g., memory cells storing data “0” but being erroneously read as storing data “1”), thereby enhancing the error correction capability of the ECC decoder 217b.

Meanwhile, the width a₁ of the LLR section I_a₂ of the MSB page may be greater than the width a₂ of the LLR section I_a₃ of the USB page (e.g., a₁>a₂). Accordingly, LLR values with the same reliability (e.g., LLR values with the same absolute value of 1) may be applied to both the memory cells included in the LLR section I_a₂ of the MSB page and the memory cells included in the LLR section I_a₃ of the USB page. However, the number of memory cells with a reliability of “1” applied thereto, among the memory cells storing data “1” but being erroneously read as storing data “0,” may be greater for the MSB page than for the USB page.

In other words, for the MSB page, which has a higher likelihood of readout errors compared to the USB page, LLR values with a lower reliability may be applied to more memory cells, thereby enhancing the error correction capability of the ECC decoder 217b.

Similarly, the width b₁ of the LLR section I_b₂ of the MSB page may be greater than the width b₂ of the LLR section I_b₃ of the USB page (e.g., b₁>b₂). Accordingly, LLR values with the same reliability (e.g., LLR values with the same absolute value of 1) may be applied to both the memory cells included in the LLR section I_b₂ of the MSB page and the memory cells included in the LLR section I_b₃ of the USB page. However, the number of memory cells with a reliability of “1” applied thereto, among the memory cells storing data “0” but being erroneously read as storing data “1,” may be greater for the MSB page than for the USB page.

In other words, for the MSB page, which has a higher likelihood of readout errors compared to the USB page, LLR values with a lower reliability may be applied to more memory cells, thereby enhancing the error correction capability of the ECC decoder 217b.

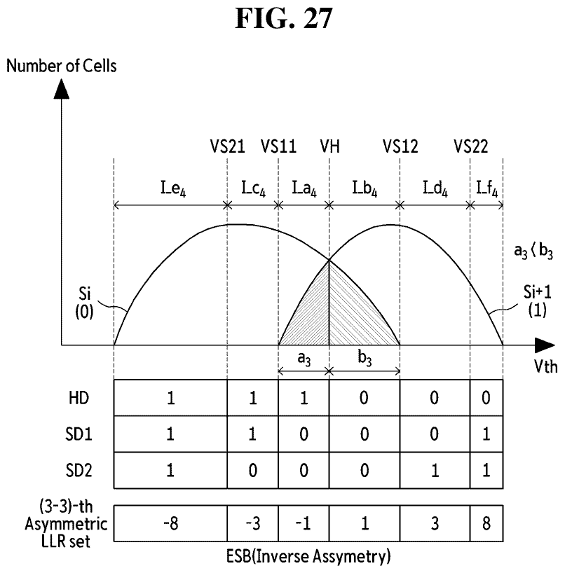

Referring to FIG. 27, the (3-3)-th asymmetric LLR set may include a plurality of LLR sections I_a₄, I_b₄, I_c₄, I_d₄, I_e₄, and I_f₄. The LLR section I_a₄ may correspond to the section between the reference read voltage VH and the (1-1)-th soft-decision read voltage VS11, and the LLR section I_b₄ may correspond to the section between the reference read voltage VH and the (1-2)-th soft-decision read voltage VS12. Similarly, the LLR section I_c₄ may correspond to the section between the (1-1)-th soft-decision read voltage VS11 and the (2-1)-th soft-decision read voltage VS21, and the LLR section I_d₄ may correspond to the section between the (1-2)-th soft-decision read voltage VS12 and the (2-2)-th soft-decision read voltage VS22. The LLR section I_e₄ may correspond to the section where the threshold voltage values of memory cells are smaller than the (2-1)-th soft-decision read voltage VS21, and the LLR section I_f₄ may correspond to the section where the threshold voltage values of memory cells are greater than the (2-2)-th soft-decision read voltage VS22.

For the ESB page, since the probability of memory cells storing data “0” being erroneously read as storing data “1” is greater than the probability of memory cells storing data “1” being erroneously read as storing data “0,” LLR values with a lower reliability need to be applied to memory cells storing data “0” but being erroneously read as storing data “1” than to memory cells storing data “1” but being erroneously read as storing data “0.”

In this case, the (3-3)-th asymmetric LLR set selected by the LLR set selection circuit 220 may include (3-3)-th LLR values of −8, −3, −1, 1, 3, and 8, which have symmetric absolute values with respect to the reference read voltage VH. However, the widths of the LLR sections corresponding to these LLR values may differ.

For example, a width b₃ of the LLR section I_b₄ may be greater than a width a₃ of the LLR section I_a₄ (e.g., b₃>a₃). Accordingly, LLR values with the same reliability (e.g., LLR values with the same absolute value of 1) may be applied to both the memory cells included in the LLR section I_a₄ and the memory cells included in the LLR section I_b₄. However, the number of memory cells with a reliability of “1” applied thereto, among the memory cells storing data “0” but being erroneously read as storing data “1,” may be greater than the number of memory cells with the reliability of “1” applied thereto, among the memory cells storing data “1” but being erroneously read as storing data “0.”

Therefore, for the ESB page, ECC decoding may be performed by applying LLR values with the same reliability to both memory cells storing data “1” but being erroneously read as storing data “0” and memory cells storing data “0” but being erroneously read as storing data “1.” However, LLR values with a lowest reliability (e.g., a smallest absolute values) may be applied more frequently to memory cells with a greater number of readout errors (e.g., memory cells storing data “0” but being erroneously read as storing data “1”) than to memory cells with a smaller number of readout errors (e.g., memory cells storing data “1” but being erroneously read as storing data “0”), thereby enhancing the error correction capability of the ECC decoder 217b.

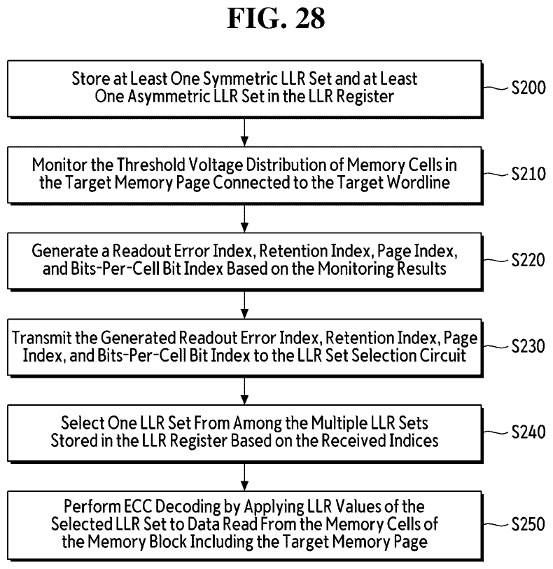

FIG. 28 is a flowchart illustrating a method of operating a storage device according to some embodiments.

The embodiment of FIG. 28 will hereinafter be described, omitting redundant descriptions and focusing mainly on the differences from the previous embodiments.

Referring to FIGS. 12 and 28, at least one symmetric LLR set and at least one asymmetric LLR set may first be stored in the LLR set register 410 (S200). Thereafter, the LLR optimization circuit 219 may monitor the threshold voltage distributions of memory cells in a target memory page connected to a target wordline (S210). For example, the LLR optimization circuit 219 may select one wordline, e.g., the target wordline, among the plurality of wordlines WL1 through WLn included in the memory cell array 330 shown in FIG. 4, to monitor the threshold voltage distribution.

Additionally, the LLR optimization circuit 219 may select one page to be monitored, e.g., a target memory page, from among a plurality of pages constituting the target wordline. For example, if the memory cell array 330 includes 4-bit QLCs, the LLR optimization circuit 219 may select one of the MSB page, USB page, ESB page, and LSB page of the target wordline as the target memory page.

Thereafter, the LLR optimization circuit 219 may generate a readout error index E_IDX, a retention index R_IDX, a page index P_IDX, and a bits-per-cell index B_IDX based on the results of monitoring the threshold voltage distributions of the memory cells in the target memory page (S220).

Thereafter, the LLR optimization circuit 219 may transmit the generated readout error index E_IDX, retention index R_IDX, page index P_IDX, and bits-per-cell index B_IDX to the LLR set selection circuit 220 (S230).

Thereafter, the LLR set selection circuit 220 may select one LLR set from among a plurality of LLR sets stored in the LLR set register 410 based on at least one of the received indices from the LLR optimization circuit 219 (S240). At this time, if the LLR set selection circuit 220 determines based on the received indices that the deviation between the probability of data at the first logic level being erroneously read as data at the second logic level and the probability of data at the second logic level being erroneously read as data at the first logic level is smaller than a desired and/or alternatively predetermined threshold, the LLR set selection circuit 220 may select a symmetric LLR set from among the LLR sets stored in the LLR set register 410.

Conversely, if the LLR set selection circuit 220 determines based on the received indices that the deviation between the probability of data at the first logic level being erroneously read as data at the second logic level and the probability of data at the second logic level being erroneously read as data at the first logic level is greater than the desired and/or alternatively predetermined threshold, the LLR set selection circuit 220 may select an asymmetric LLR set from among the LLR sets stored in the LLR set register 410.

At this time, the LLR set selection circuit 220 may also determine the magnitude of asymmetry between the probability of data at the first logic level being erroneously read as data at the second logic level and the probability of data at the second logic level being erroneously read as data at the first logic level. If the LLR set selection circuit 220 determines that the asymmetry is relatively large, it may select an asymmetric LLR set including LLR values whose absolute values have a relatively large asymmetry with respect to a reference read voltage from among the asymmetric LLR sets stored in the LLR set register 410.

Thereafter, the ECC decoder 217b may perform ECC decoding by applying the LLR values of the LLR set selected by the LLR set selection circuit 220 to data read from the memory cells of the target memory page and data read from the memory cells of the memory block including the target memory page (S250).

For example, referring to FIG. 4, if the wordline WL(2) is the target wordline, the memory page MP constituting the wordline WL(2) may be the target memory page. If the memory cells MC1 constituting the memory cell array 330 are MLCs, there may be multiple memory pages constituting the target wordline, and one of the multiple memory pages constituting the target wordline may be set as the target memory page.

Once the memory page MP is set as the target memory page, the ECC decoder 217b may perform ECC decoding by applying the LLR values of the LLR set selected by the LLR set selection circuit 220 for decoding data read from the memory cells of the memory page MP to all the data read from the memory cells of the memory block MB including the memory page MP.

In other words, the LLR optimization circuit 219 may generate a retention index R_IDX only for a single target memory page MP without the need to perform a readout operation on all the memory pages MP included in the same memory block MB and generate a retention index R_IDX for each of the memory pages MP. At this time, the LLR set selection circuit 220 may select one LLR set from among the LLR sets stored in the LLR set register 410 based on the retention index R_IDX for the target memory page MP. The ECC decoder 217b may perform ECC decoding by applying the selected LLR set not only to the memory cells of the target memory page MP but also to the memory cells included in the memory block MB including the target memory page MP. Accordingly, the efficiency of the error correction operation of the ECC decoder 217b can be improved.

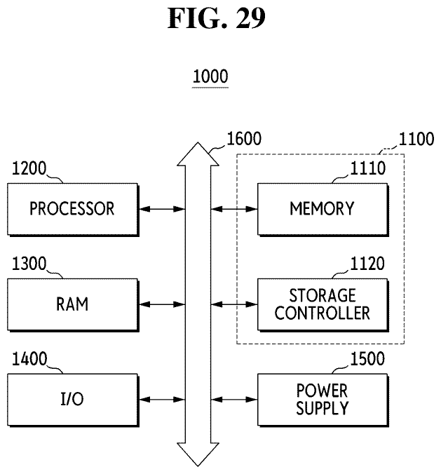

FIG. 29 is a diagram illustrating a computing system including a storage device according to some embodiments.

Referring to FIG. 29, a computing system 1000 may include a storage device 1100, a processor 1200, a random-access memory (RAM) 1300, an input/output device (“I/O”) 1400, and a power supply unit 1500. The storage device 1100 may include a memory device 1110 and a storage controller 1120. The memory device 1110 and the storage controller 1120 may implement the memory device 300A, 300B, or 300C and the storage controller 200, respectively, illustrated in FIGS. 1 through 3.

Meanwhile, the computing system 1000 may further include ports capable of communicating with video cards, sound cards, memory cards, USB devices, or other electronic devices. The computing system 1000 may be implemented as a personal computer (PC), a laptop computer, a mobile phone, a personal digital assistant (PDA), or a portable electronic device such as a camera.

The processor 1200 may perform specific calculations or tasks. The processor 1200 may be a microprocessor or a central processing unit (CPU). The processor 1200 may communicate with the RAM 1300, the input/output device 1400, and the storage device 1100 via buses 1600 such as an address bus, a control bus, and a data bus. In some embodiments, the processor 1200 may also be connected to an expansion bus such as a Peripheral Component Interconnect (PCI) bus.

The RAM 1300 may store data necessary for the operation of the computing system 1000. For example, the RAM 1300 may be implemented as a dynamic RAM (DRAM), mobile DRAM, static RAM (SRAM), phase-change RAM (PRAM), ferroelectric RAM (FRAM), resistive RAM (RRAM), and/or magnetoresistive RAM (MRAM).

The input/output device 1400 may include input means such as a keyboard, keypad, or mouse and output means such as a printer or display. The power supply unit 1500 may provide the operating voltage necessary for the operation of the computing system 1000.

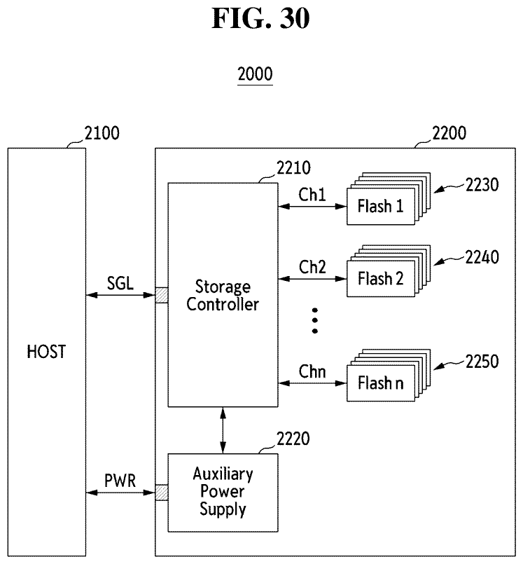

FIG. 30 is a diagram illustrating an example of applying a storage device to a solid-state drive (SSD) system according to some embodiments.

Referring to FIG. 30, an SSD system 2000 may include a host 2100 and an SSD 2200. The host 2100 and the SSD 2200 may implement the host 20 and the storage device 100, respectively, illustrated in FIG. 1. The SSD 2200 may transmit and receive signals with the host 2100 through a signal connector SGL and receive power through a power connector PWR. The SSD 2200 may include a storage controller 2210, an auxiliary power supply unit 2220, and a plurality of memory devices 2230, 2240, and 2250. The storage controller 2210 and the memory devices 2230, 2240, and 2250 may implement the storage controller 200 and the memory devices 300A, 300B, and 300C, respectively, illustrated in FIGS. 1 through 3.

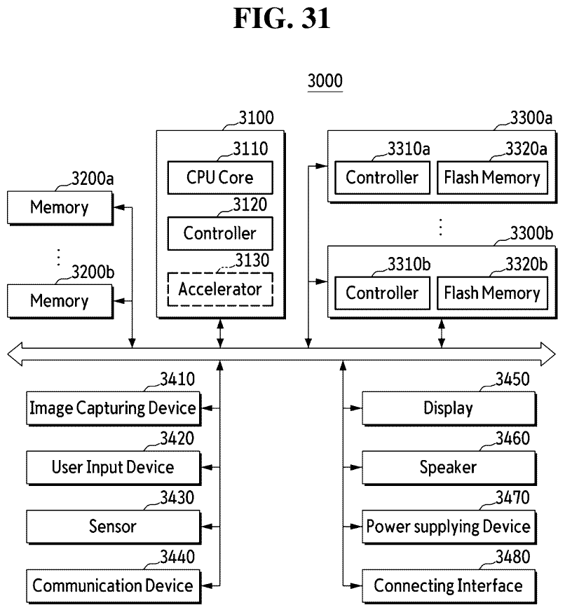

FIG. 31 is a diagram illustrating a system including a memory device according to some embodiments.

Referring to FIG. 31, a system 3000 may primarily be a mobile system such as a mobile phone, a smartphone, a tablet personal computer (PC), a wearable device, a healthcare device, or an Internet of Things (IoT) device. However, the system 3000 is not limited to a mobile system and may also be a PC, a laptop computer, a server, a media player, or an automotive device such as a navigation system.

Referring to FIG. 31, the system 3000 may include a main processor 3100, memories 3200a and 3200b, and storage devices 3300a and 3300b, and may further include at least one of an image capturing device 3410, a user input device 3420, a sensor 3430, a communication device 3440, a display 3450, a speaker 3460, a power supplying device 3470, and a connecting interface 3480. The storage devices 3300a and 3300b may implement the storage device 100 illustrated in FIGS. 1 through 3.

The main processor 3100 may control the overall operation of the system 3000, particularly, the operations of other components constituting the system 3000. The main processor 3100 may be implemented as a general-purpose processor, a dedicated processor, or an application processor.

The main processor 3100 may include at least one CPU core 3110 and may further include a controller 3120 for controlling the memories 3200a and 3200b and/or the storage devices 3300a and 3300b. In some embodiments, the main processor 3100 may further include an accelerator block 3130, which is a dedicated circuit for high-speed data operations such as artificial intelligence (AI) data operations. The accelerator block 3130 may include a graphics processing unit (GPU), a neural processing unit (NPU), and/or a data processing unit (DPU) and may be implemented as a separate chip physically independent of other components of the main processor 3100.

The memories 3200a and 3200b may be used as main memories for the system 3000 and may include volatile memories such as SRAMs and/or DRAMs, or non-volatile memories such as flash memories, PRAMs, and/or RRAMs. The memories 3200a and 3200b may also be implemented within the same package as the main processor 3100.

The storage devices 3300a and 3300b may function as non-volatile storage devices capable of storing data regardless of power supply and may have a relatively large storage capacity compared to the memories 3200a and 3200b. The storage devices 3300a and 3300b may include controllers 3310a and 3310b and non-volatile storage devices 3320a and 3320b, which store data under the control of the controllers 3310a and 3310b. The non-volatile storage devices 3320a and 3320b may include 2D or 3D V-NAND flash memories but may also include other types of non-volatile memories such as PRAMs and/or RRAMs.

The storage devices 3300a and 3300b may be included in the system 3000 in a physically separate state from the main processor 3100 or may be implemented within the same package as the main processor 3100. Additionally, the storage devices 3300a and 3300b may take the form of memory cards and be detachably coupled to other components of the system 3000 through an interface such as the connecting interface 3480. The storage devices 3300a and 3300b may be devices to which standard protocols such as Universal Flash Storage (UFS) are applied but are not limited thereto.

The image capturing device 3410 may capture still images or videos and may be implemented as a camera, camcorder, and/or webcam.

The user input device 3420 may receive various types of data input from a user of the system 3000 and may include a touch pad, keypad, keyboard, mouse, and/or microphone.

The sensor 3430 may detect various types of physical quantities that can be obtained externally to the system 3000 and convert the detected physical quantities into electrical signals. The sensor 3430 may include a temperature sensor, pressure sensor, light sensor, position sensor, acceleration sensor, biosensor, and/or gyroscope.

The communication device 3440 may transmit and receive signals between the system 3000 and other external devices in accordance with various communication protocols. The communication device 3440 may include an antenna, transceiver, and/or modem.

The display 3450 and the speaker 3460 may function as output devices for outputting visual information and auditory information, respectively, to the user of the system 3000.

The power supplying device 3470 may convert power supplied from an internal battery and/or an external power source into a suitable form and provide it to the components of the system 3000.

The connecting interface 3480 may provide a connection between the system 3000 and an external device capable of transmitting and receiving data with the system 1000. The connecting interface 3480 may be implemented using various interface methods such as Advanced Technology Attachment (ATA), Serial ATA (SATA), e-SATA (external SATA), Small Computer System Interface (SCSI), Serial Attached SCSI (SAS), Peripheral Component Interconnection (PCI), PCI express (PCIe), NVM express (NVMe), IEEE 1394, Universal Serial Bus (USB), Secure Digital (SD) card, Multi-Media Card (MMC), embedded Multi-Media Card (eMMC), Universal Flash Storage (UFS), embedded Universal Flash Storage (eUFS), and Compact Flash (CF) card interfaces.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

In concluding the detailed description, those skilled in the art will appreciate that many variations and modifications may be made to the presented embodiments without substantially departing from the principles of inventive concepts. Therefore, the presented embodiments should be used in a generic and descriptive sense only and not for purposes of limitation.

What is claimed is:

1. A storage device comprising:
a memory device including a memory cell array, the memory cell array including a plurality of wordlines and first memory cells of a first memory page, the first memory cells of the first memory page being connected to a target wordline among the plurality of wordlines;
a storage controller configured to control an operation of the memory device;
a log likelihood ratio (LLR) optimization circuit configured to generate a first readout error index for data stored in the first memory cells; and
an LLR set register configured to store a symmetric LLR set and an asymmetric LLR set, the symmetric LLR set including first LLR values having symmetric absolute values with respect to a reference read voltage, and the asymmetric LLR set including second LLR values having asymmetric absolute values with respect to the reference read voltage, wherein
the storage controller includes an LLR set selection circuit and a decoder,
the LLR set selection circuit is configured to receive the first readout error index from the LLR optimization circuit and select one of the symmetric LLR set and the asymmetric LLR set stored in the LLR set register based on the first readout error index,
the decoder is configured to perform error correction code (ECC) decoding by applying LLR values of the one of the symmetric LLR set and the asymmetric LLR set that is selected by the LLR set selection circuit to data read from the first memory cells,
the first readout error index includes information regarding a probability of data at a first logic level stored in the first memory cells being erroneously read as data at a second logic level and information regarding a probability of data at the second logic level stored in the first memory cells being erroneously read as data at the first logic level, and
the second logic level is different than the first logic level.

2. The storage device of claim 1, wherein
the memory cell array further includes second memory cells of a second memory page connected to the target wordline,
the LLR optimization circuit is configured to generate a second readout error index for data stored in the second memory cells,
the LLR set selection circuit is configured to receive the second readout error index from the LLR optimization circuit and select a selected one of the symmetric LLR set and the asymmetric LLR set stored in the LLR set register based on the second readout error index, and
the decoder is configured to perform ECC decoding by applying LLR values of the selected one of the symmetric LLR set and the asymmetric LLR set that is selected by the LLR set selection circuit to data read from the second memory cells,
the second readout error index includes information regarding a probability of data at the first logic level stored in the second memory cells being erroneously read as data at the second logic level and information regarding a probability of data at the second logic level stored in the second memory cells being erroneously read as data at the first logic level, and
the first memory page and the second memory page are different memory pages corresponding to the target wordline.

3. The storage device of claim 1, wherein in response to a deviation between the probability of the data at the first logic level stored in the first memory cells being erroneously read as data at the second logic level and the probability of the data at the second logic level stored in the first memory cells being erroneously read as data at the first logic level being equal to or greater than a threshold value, based on the first readout error index, the LLR set selection circuit is configured to selects the asymmetric LLR set stored in the LLR set register for ECC decoding of the data read from the first memory cells.

4. The storage device of claim 3, wherein during ECC decoding, in response to the probability of the data at the first logic level stored in the first memory cells being erroneously read as data at the second logic level being greater than the probability of the data at the second logic level stored in the first memory cells being erroneously read as data at the first logic level, the LLR set selection circuit is configured to make absolute values of the second LLR values applied to the data from the first memory cells erroneously read as data at the second logic level smaller than absolute values of the second LLR values applied to the data from the first memory cells erroneously read as data at the first logic level.

5. The storage device of claim 1, wherein in response to a deviation between the probability of the data at the first logic level stored in the first memory cells being erroneously read as data at the second logic level and the probability of the data at the second logic level stored in the first memory cells being erroneously read as data at the first logic level being smaller than a threshold, the LLR set selection circuit is configured to selects the symmetric LLR set stored in the LLR set register for ECC decoding of the data read from the first memory cells, based on the first readout error index.

6. The storage device of claim 5, wherein during ECC decoding, absolute values of the first LLR values applied to the data from the first memory cells erroneously read as data at the second logic level are made equal to absolute values of the first LLR values applied to the data from the first memory cells erroneously read as data at the first logic level.

7. The storage device of claim 1, wherein
the LLR optimization circuit is configured to transmit a bits-per-cell index to the LLR set selection circuit,
the bits-per-cell index includes information regarding a number of bits stored in each of the first memory cells, and
the LLR set selection circuit is configured to select the one of the symmetric LLR set and the asymmetric LLR set stored in the LLR set register for ECC decoding of the data read from the first memory cells, based on the bits-per-cell index.

8. The storage device of claim 1, wherein
the LLR optimization circuit is configured to transmits a retention index to the LLR set selection circuit,
the retention index includes information regarding a shift in a threshold voltage distribution of the first memory cells due to retention, and
the LLR set selection circuit is configured to select the one of the symmetric LLR set and the asymmetric LLR set stored in the LLR set register for ECC decoding of the data read from the first memory cells, based on the retention index.

9. The storage device of claim 8, wherein in response to a reference threshold voltage value of memory cells in a highest program state among the first memory cells being smaller than a threshold voltage value, the LLR set selection circuit is configured to select the asymmetric LLR set stored in the LLR set register for ECC decoding of the data read from the first memory cells, based on the retention index.

10. A storage device comprising:
a memory device including a memory cell array, the memory cell array including a plurality of wordlines and first memory cells of a first memory page, the first memory cells of the first memory page being connected to a target wordline among the plurality of wordlines;
a storage controller configured to control an operation of the memory device;
a log likelihood ratio (LLR) optimization circuit configured to generate a first readout error index for data stored in the first memory cells; and
an LLR set register configured to store a symmetric LLR set and a first asymmetric LLR set, the symmetric LLR set including first LLR sections having symmetric widths with respect to a reference read voltage, the first asymmetric LLR set including second LLR sections having asymmetric widths with respect to the reference read voltage, wherein
the storage controller includes an LLR set selection circuit and a decoder,
the LLR set selection circuit is configured to receive the first readout error index from the LLR optimization circuit and select one of the symmetric LLR set and the first asymmetric LLR set stored in the LLR set register based on the first readout error index,
the decoder is configured to perform error correction code (ECC) decoding by applying LLR values corresponding to respective LLR sections of the one of the symmetric LLR set and the first asymmetric LLR set that is selected by the LLR set selection circuit to data read from the first memory cells,
the first readout error index includes information regarding a probability of data at a first logic level stored in the first memory cells being erroneously read as data at a second logic level and information regarding a probability of data at the second logic level stored in the first memory cells being erroneously read as data at the first logic level, and
the second logic level is different from the first logic level.

11. The storage device of claim 10, wherein
the symmetric LLR set includes first LLR values corresponding to the respective first LLR sections, and
the first LLR values have symmetric absolute values with respect to the reference read voltage.

12. The storage device of claim 10, wherein
the first asymmetric LLR set includes second LLR values corresponding to the respective second LLR sections, and
the second LLR values have asymmetric absolute values with respect to the reference read voltage.

13. The storage device of claim 10, wherein
the memory cell array further includes second memory cells of a second memory page connected to the target wordline,
the LLR optimization circuit is configured to generate a second readout error index for data stored in the second memory cells,
the LLR set selection circuit is configured to receive the second readout error index from the LLR optimization circuit and select a selected one of the symmetric LLR set and the first asymmetric LLR set stored in the LLR set register based on the second readout error index,
the decoder is configured to perform ECC decoding by applying LLR values corresponding to respective LLR sections of the selected one of the symmetric LLR set and the first asymmetric LLR set that is selected by the LLR set selection circuit to data read from the second memory cells,
the second readout error index includes information regarding a probability of data at the first logic level stored in the second memory cells being erroneously read as data at the second logic level and information regarding a probability of data at the second logic level stored in the second memory cells being erroneously read as data at the first logic level, and
the first memory page and the second memory page are different memory pages corresponding to the target wordline.

14. The storage device of claim 10, wherein in response to a deviation between the probability of the data at the first logic level stored in the first memory cells being erroneously read as data at the second logic level and the probability of the data at the second logic level stored in the first memory cells being erroneously read as data at the first logic level being equal to or greater than a threshold, based on the first readout error index, the LLR set selection circuit is configured to select the first asymmetric LLR set stored in the LLR set register for ECC decoding of the data read from the first memory cells.

15. The storage device of claim 14, wherein
the second LLR sections include a first section and a second section divided by the reference read voltage,
a probability of the first memory cells included in the first section being erroneously read is greater than a probability of the first memory cells included in the second section being erroneously read, and
a width of the first section is greater than a width of the second section.

16. The storage device of claim 10, wherein in response to a deviation between the probability of the data at the first logic level stored in the first memory cells being erroneously read as data at the second logic level and the probability of the data at the second logic level stored in the first memory cells being erroneously read as data at the first logic level being smaller than a threshold, the LLR set selection circuit is configured to select the symmetric LLR set stored in the LLR set register for ECC decoding of the data read from the first memory cells, based on the first readout error index.

17. The storage device of claim 16, wherein
the first LLR sections include a first section and a second section divided by the reference read voltage, and
a width of the first section is equal to a width of the second section.

18. The storage device of claim 13, wherein
the memory cell array further includes third memory cells of a third memory page connected to the target wordline,
the LLR optimization circuit is configured to generate a third readout error index for data stored in the third memory cells,
the LLR set register is configured to store a second asymmetric LLR set including third LLR sections having asymmetric widths with respect to the reference read voltage,
the LLR set selection circuit is configured to receive the third readout error index from the LLR optimization circuit and select a selected LLR set based on the third readout error index, the selected LLR set being one of the symmetric LLR set, the first asymmetric LLR set, and the second asymmetric LLR set stored in the LLR set register,
the decoder is configured to perform ECC decoding by applying LLR values corresponding to respective LLR sections of the selected LLR set that is selected by the LLR set selection circuit to data read from the third memory cells,
the third readout error index includes information regarding a probability of data at the first logic level stored in the third memory cells being erroneously read as data at the second logic level and information regarding a probability of data at the second logic level stored in the third memory cells being erroneously read as data at the first logic level, and
the first memory page, the second memory page, and the third memory page are different memory pages corresponding to the target wordline.

19. The storage device of claim 18, wherein
the second LLR sections include a first section and a second section divided by the reference read voltage,
the third LLR sections include a third section and a fourth section divided by the reference read voltage,
a width of the first section is greater than a width of the third section,
LLR values corresponding to the first section and the third section are equal,
LLR values corresponding to the second section and the fourth section are equal, and
LLR values corresponding to the first section and the second section are different.

20. A storage device comprising:
a memory device including a memory cell array, the memory cell array including first memory cells of a first memory page connected to a first wordline, second memory cells of a second memory page connected to a second wordline, and a memory block including the first memory page and the second memory page;
a storage controller configured to control an operation of the memory device;
a log likelihood ratio (LLR) optimization circuit configured to generate a readout error index for data stored in the first memory cells; and
an LLR set register configured to store a symmetric LLR set including first LLR values having symmetric absolute values with respect to a reference read voltage and an asymmetric LLR set including second LLR values having asymmetric absolute values with respect to the reference read voltage, wherein
the storage controller includes an LLR set selection circuit and a decoder,
the LLR set selection circuit is configured to receive the readout error index from the LLR optimization circuit and select one of the symmetric LLR set and the asymmetric LLR set stored in the LLR set register based on the readout error index,
the decoder is configured to perform error correction code (ECC) decoding by applying LLR values of the one of the symmetric LLR set and the asymmetric LLR set that is selected by the LLR set selection circuit to data read from the first memory cells and the second memory cells, and
the readout error index includes information regarding a probability of data at a first logic level stored in the first memory cells being erroneously read as data at a second logic level different from the first logic level and information regarding a probability of data at the second logic level stored in the first memory cells being erroneously read as data at the first logic level.
